(19) United States
(12) Patent Application Publication
(10) Pub. No.: US 2012/0189818 A1
(43) Pub. Date: Jul. 26, 2012

(54) STRUCTURE AND METHOD FOR MANUFACTURING THE SAME

(75) Inventor: Katsura Hayashi, Yasu-shi (JP)

(73) Assignee: Kyocera Corporation, Kyoto (JP)

(21) Appl. No.: 13/498,802

(22) PCT Filed: Sep. 28, 2010
(86) PCT No.: PCT/JP2010/066844

§ 371 Date: Apr. 11, 2012

(30) Foreign Application Priority Data
Sep. 28, 2009 (JP) 2009-222549
Oct. 29, 2009 (JP) 2009-249351
Oct. 29, 2009 (JP) 2009-249352
Dec. 26, 2009 (JP) 2009-296517
Dec. 26, 2009 (JP) 2009-296518

(51) Int. Cl. B32B 5/16; H05K 3/00; H05K 1/02; B32B 5/30; B32B 3/30

(52) U.S. Cl. 428/161; 428/402; 428/323; 427/99.2

(57) ABSTRACT

A circuit board includes an inorganic insulating layer having first inorganic insulating particles connected to each other, and second inorganic insulating particles connected to each other via the first inorganic insulating particles and having a larger particle diameter than that of the first inorganic insulating particles. A circuit board manufacturing method includes applying an inorganic insulating sol including first inorganic insulating particles and second inorganic insulating particles having a larger particle diameter than that of the first inorganic insulating particles, and heating the first inorganic insulating particles and the second inorganic insulating particles at a temperature lower than a crystallization onset temperature of the first inorganic insulating particles and lower than a crystallization onset temperature of the second inorganic insulating particles, and connecting the first inorganic insulating particles to each other, and connecting second insulating particles to each other via the first insulating particles.

### TECHNICAL FIELD

The present invention relates to a structure used for all objects, such as electronic devices (for example, a variety of audio-visual devices, home appliances, communication devices, computer devices, and peripheral devices thereof), transport air planes, and buildings, and a method for manufacturing the same.

### BACKGROUND ART

There has been known a circuit board having a resin layer and a ceramic layer as a circuit board used for electronic devices.

For example, Japanese Unexamined Patent Publication JP-A 2-253941 (1990) describes a circuit board formed by thermally spraying ceramic on one surface of a metallic foil so as to form a ceramic layer, laminating a prepreg so as to come into contact with the metallic foil on the ceramic layer side, and thermocompressionally molding the laminated body.

However, in general, since the ceramic layer is highly stiff and easily broken, in a case in which a stress is applied to the circuit board, cracks are liable to occur in the ceramic layer. Therefore, when the cracks extend and reach wires, breaking is liable to occur in the wires, and, furthermore, the electrical reliability of the circuit board becomes liable to degrade.

Consequently, there is a demand for provision of a circuit board for which the electrical reliability is improved.

### SUMMARY OF INVENTION

The invention solves the above demand by providing a structure for which the electrical reliability is improved.

A structure according to an embodiment of the invention comprises an inorganic insulating layer comprising first inorganic insulating particles connected to each other, and second inorganic insulating particles connected to each other via the first inorganic insulating particles and having a larger particle diameter than a particle diameter of the first inorganic insulating particles.

A method for manufacturing a structure according to an embodiment of the invention comprises applying an inorganic insulating sol comprising first inorganic insulating particles and second inorganic insulating particles having a larger particle diameter than a particle diameter of the first inorganic insulating particles, and heating the first inorganic insulating particles and the second inorganic insulating particles at a temperature lower than a crystallization onset temperature of the first inorganic insulating particles and lower than a crystallization onset temperature of the second inorganic insulating particles, and connecting the first inorganic insulating particles to each other, and connecting the second insulating particles to each other via the first insulating particles.

### BRIEF DESCRIPTION OF DRAWINGS

FIG. 1 is a cross-sectional view of a mounting structure having a circuit board according to a first embodiment of the invention, which is cut in a thickness direction thereof;

FIG. 2A is an enlarged cross-sectional view showing an R1 section in the mounting structure as shown in FIG. 1, and FIG. 2B is a view schematically showing an appearance of two first inorganic insulating particles connected to each other;

FIG. 3A is an enlarged cross-sectional view showing an R2 section in the mounting structure as shown in FIG. 1, and FIG. 3B is an enlarged cross-sectional view showing an R3 section in the mounting structure as shown in FIG. 2A;

FIGS. 4A and 4B are cross-sectional views of the circuit board cut in the thickness direction thereof which explain steps for manufacturing the circuit board as shown in FIG. 1, and FIG. 4C is an enlarged cross-sectional view showing an R4 section in FIG. 4B;

FIGS. 5A to 5C are cross-sectional views of the circuit board cut in the thickness direction thereof which explain steps for manufacturing the circuit board as shown in FIG. 1;

FIGS. 6A to 6C are cross-sectional views of the circuit board cut in the thickness direction thereof which explain steps for manufacturing the circuit board as shown in FIG. 1;

FIGS. 7A and 7B are cross-sectional views of the circuit board cut in the thickness direction thereof which explain steps for manufacturing the circuit board as shown in FIG. 1;

FIG. 8A is a cross-sectional view of a mounting structure having a circuit board according to a second embodiment of the invention, which is cut in a thickness direction thereof, and FIG. 8B is an enlarged cross-sectional view showing an R5 section in the mounting structure as shown in FIG. 8A;

FIG. 9A is a cross-sectional view cut in a planar direction along the line I-I in FIG. 8B, and FIG. 9B is an enlarged cross-sectional view showing an R6 section in the mounting structure as shown in FIG. 8A;

FIG. 10A is a cross-sectional view of the circuit board cut in the thickness direction thereof which explains a step for manufacturing the circuit board as shown in FIG. 8A, FIG. 10B is an enlarged cross-sectional view showing an R7 section in FIG. 10A, and FIG. 10C is an enlarged cross-sectional view showing a section corresponding to the R7 section in FIG. 10A which explains a step for manufacturing the circuit board as shown in FIG. 8A;

FIGS. 11A and 11B are enlarged cross-sectional views showing the section corresponding to the R7 section in FIG. 10A which explain a step for manufacturing the circuit board as shown in FIG. 8A;

FIG. 12A is a cross-sectional view of a mounting structure having a circuit board according to a third embodiment of the invention, which is cut in a thickness direction thereof, and FIG. 12B is an enlarged cross-sectional view showing an R8 section in the mounting structure as shown in FIG. 12A;

FIG. 13A is a cross-sectional view cut in a planar direction along the line II-II in FIG. 12B, and FIG. 13B is an enlarged cross-sectional view showing an R9 section in the mounting structure as shown in FIG. 12A;

FIGS. 14A and 14B are cross-sectional views of the circuit board cut in the thickness direction thereof which explain steps for manufacturing the circuit board as shown in FIG. 12A, and FIG. 14C is an enlarged cross-sectional view showing an R10 section in FIG. 14B;

FIGS. 15A and 15B are enlarged cross-sectional view showing a section corresponding to the R10 section in FIG. 14B which explains a step for manufacturing the circuit board as shown in FIG. 12A;

FIGS. 16A and 16B are photographs of a part of a cross section of a laminated plate of Sample 1 cut in a thickness direction thereof, which are taken using a field emission scanning electron microscope;

FIG. 17A is an enlarged photograph of an R11 section in FIG. 16B, and FIG. 17B is a photograph of a part of a cross section of a laminated plate of Sample 5 cut in a thickness direction thereof, which is taken using a field emission scanning electron microscope;

FIG. 18A is an enlarged photograph of an R12 section in FIG. 17B, and FIG. 18B is a photograph of a part of a cross section of a laminated plate of Sample 6 cut in a thickness direction thereof, which is taken using a field emission scanning electron microscope;

FIG. 19A is a photograph of a part of a cross section of a laminated plate of Sample 12 cut in a thickness direction thereof, which is taken using a field emission scanning electron microscope, and FIG. 19B is an enlarged photograph of an R13 section in FIG. 19A;

FIG. 20A is a photograph of a part of a cross section of a laminated plate of Sample 16 cut in a thickness direction thereof, which is taken using a field emission scanning electron microscope, and FIG. 20B is a photograph of a part of a cross section of an inorganic insulating layer in the laminated plate of Sample 16 cut in a planar direction thereof, which is taken using a field emission scanning electron microscope;

FIGS. 21A and 21B are photographs of a part of a cross section of the inorganic insulating layer in the laminated plate of Sample 16 cut in the planar direction thereof, which are taken using a field emission scanning electron microscope;

FIG. 22A is a photograph of a part of a cross section of a laminated plate of Sample 17 cut in a thickness direction thereof, which is taken using a field emission scanning electron microscope, and FIG. 22B is a photograph of a part of a cross section of a laminated plate of Sample 18 cut in a thickness direction thereof, which is taken using a field emission scanning electron microscope; FIG. 23A is a photograph of a part of a cross section of a laminated plate of Sample 19 cut in a thickness direction thereof, which is taken using a field emission scanning electron microscope, and FIG. 23B is a photograph of a part of a cross section of a laminated plate of Sample 20 cut in a thickness direction thereof, which is taken using a field emission scanning electron microscope;

FIG. 24 is a photograph of a part of a cross section of a laminated plate of Sample 21 cut in a thickness direction thereof, which is taken using a field emission scanning electron microscope; and

FIG. 25A is a photograph of a part of a cross section of a laminated plate of Sample 22 cut in a thickness direction thereof, which is taken using a field emission scanning electron microscope, and FIG. 25B is a photograph of a part of a cross section of a laminated plate of Sample 22 cut in a planar direction thereof, which is taken using a field emission scanning electron microscope.

### DESCRIPTION OF EMBODIMENTS

### First Embodiment

Hereinafter, a circuit board according to a first embodiment of the invention will be described in detail based on the accompanying drawings.

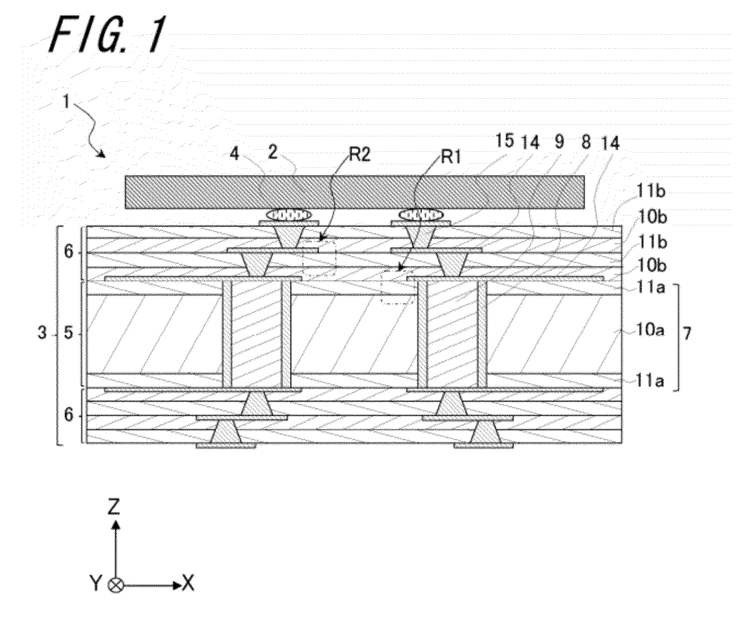

A circuit board 3 as shown in FIG. 1 is used for electronic devices, for example, a variety of audio-visual devices, home appliances, communication devices, computer devices, and peripheral devices thereof.

The circuit board 3 includes a core substrate 5 and a pair of circuit layers 6 disposed on top and bottom surfaces of the core substrate 5, and has functions of supporting an electronic component 2 and supplying, to the electronic component 2, power or signals for driving or controlling the electronic component 2.

Meanwhile, the electronic component 2 is, for example, a semiconductor element, such as an IC or LSI, and is flip-chip-mounted on the circuit board 3 via a bump 4 composed of a conductive material, such as solder. The electronic component 2 has a base material that is formed of a semiconductor material, such as silicon, germanium, gallium arsenide, gallium arsenide phosphide, gallium nitride, or silicon carbide.

Hereinafter, the configuration of the circuit board 3 will be described in detail.

(Core Substrate)

The core substrate 5 enhances the stiffness of the circuit board 3, achieves conduction between the pair of circuit layers 6, and includes a base 7 that supports the circuit layers 6, through holes provided in the base 7, cylindrical through hole conductors 8 that are provided in the through holes and electrically connect the pair of circuit layers 6, and insulating bodies 9 that are surrounded with the through hole conductors 8.

The base 7 has a first resin layer 10a and first inorganic insulating layers 11a disposed on top and bottom surfaces of the first resin layer 10a.

The first resin layer 10a forms a main portion of the base 7, and includes, for example, a resin portion and a base member coated with the resin portion. The first resin layer 10a is set to, for example, 0.1 mm or more and 3.0 mm or less in thickness, for example, 0.2 GPa or more and 20 GPa or less in Young's modulus, for example, 3 ppm/° C. or more and 20 ppm/° C. or less in coefficient of thermal expansion in a planar direction thereof, for example, 30 ppm/° C. or more and 50 ppm/° C. or less in coefficient of thermal expansion in a thickness direction thereof, and, for example, 0.01 or more and 0.02 or less in dielectric loss tangent.

Here, the Young's modulus of the first resin layer 10a is measured by the measurement method according to ISO 527-1:1993 using a commercially available tension tester. In addition, the coefficient of thermal expansion of the first resin layer 10a is measured by the measurement method according to JISK7197-1991 using a commercially available thermo-mechanical analysis (TMA) apparatus. In addition, the dielectric loss tangent of the first resin layer 10a is measured by the resonator method according to JISR1627-1996. Here, the Young's modulus, coefficient of thermal expansion, and dielectric loss tangent of each member including a second resin layer 10b and first and second inorganic insulating layers 11a and 11b are measured in the same manner as for the first resin layer 10a.

The resin portion in the first resin layer 10a can be formed of, for example, a thermosetting resin, such as an epoxy resin, a bismaleimide triazine resin, a cyanate resin, a polyphenylene ether resin, a wholly aromatic polyamide resin, or a polyimide resin. The resin portion is set to, for example, 0.1 GPa or more and 5 GPa or less in Young's modulus, and, for example, 20 ppm/° C. or more and 50 ppm/° C. or less in coefficients of thermal expansion in the thickness direction and the planar direction thereof.

The base member included in the first resin layer 10a reduces the coefficient of thermal expansion in the planar direction of the first resin layer 10a, and enhances the stiffness of the first resin layer 10a. The base member can be formed of a fiber group in which, for example, woven fabrics or non-woven fabrics composed of a plurality of fibers or a plurality of fibers are arrayed in a single direction. Examples of the fibers that can be used include a glass fiber, a resin fiber, a carbon fiber, a metal fiber, and the like.

In the embodiment, the first resin layer 10a further contains a first filler 12 composed of a number of first filler particles that are formed of an inorganic insulating material. As a result, it is possible to reduce the coefficient of thermal expansion of the first resin layer 10a, and enhance the stiffness of the first resin layer 10a. The first filler particles can be formed of an inorganic insulating material, for example, silicon oxide, aluminum oxide, aluminum nitride, aluminum hydroxide, calcium carbonate, or the like. The first filler particle is set to, for example, 0.5 μm or more and 5.0 μm or less in particle diameter, and, for example, 0 ppm/° C. or more and 15 ppm/° C. or less in coefficient of thermal expansion. In addition, the ratio of the volume of the first filler 12 to the total volume of the resin portion of the first resin layer 10a and the first filler 12 (hereinafter referred to as the “content of the first filler 12”) is set to, for example, 3% by volume or more and 60% by volume or less.

Here, the particle diameter of the first filler particles is set as follows. Firstly, a polished surface or ruptured surface of the first resin layer 10a is observed using a field emission scanning electron microscope, and a cross section that is enlarged so as to include 20 particles to 50 particles is photographed. Next, the largest size of each particle is measured on the enlarged cross section, and the measured largest particle diameter is considered as the particle diameter of the first filler particles. In addition, the content (% by volume) of the first filler 12 is measured by photographing a polished surface of the first resin layer 10a using a field emission scanning electron microscope, measuring the area proportion (% by area) of the filler 12 in the resin portion of the first resin layer 10a in cross sections at 10 places using an image analysis apparatus or the like, computing an average value of the measured values, and using the average value as the content (% by volume).

Meanwhile, the first inorganic insulating layers 11a disposed on the top and bottom surfaces of the first resin layer 10a are constituted by an inorganic insulating material, such as silicon oxide, aluminum oxide, boron oxide, magnesium oxide, calcium oxide, or the like. Since the above material has a higher stiffness than that of a resin material, the first inorganic insulating layers have a function of enhancing the stiffness of the base 7.

Since the coefficient of thermal expansion of the first inorganic insulating layer 11a in the planar direction thereof is lower than the coefficient of thermal expansion of an ordinary resin material in the planar direction, it is possible to approximate the coefficient of thermal expansion of the circuit board 3 in the planar direction thereof to the coefficient of thermal expansion of the electronic component 2 in the planar direction thereof, and warpage of the circuit board 3 due to a thermal stress can be reduced.

Since the coefficient of thermal expansion of the first inorganic insulating layer 11a in the thickness direction thereof is smaller than the coefficient of thermal expansion in the thickness direction of a resin film having a low coefficient of thermal expansion in the planar direction thereof, compared to a case in which the resin film is used, it is possible to reduce the coefficient of thermal expansion of the base 7 in the thickness direction thereof, to decrease a thermal stress caused by the difference in the coefficient of thermal expansion between the base 7 and the through hole conductor 8, and to reduce breaking of the through hole conductor 8.

Since, generally, the inorganic insulating material has a lower dielectric loss tangent than that of the resin material, and the first inorganic insulating layers 11a are disposed closer to the circuit layer 6 than the first resin layer 10a, it is possible to enhance the signal transmission characteristics of the circuit layers 6 disposed on the top and bottom surfaces of the core substrate 5.

The thickness of the first inorganic insulating layer 11a is set to, for example, 3 μm or more and 100 μm or less and/or 3% or more and 10% or less of the first resin layer 10a. In addition, the Young's modulus of the first inorganic insulating layer 11a is set to, for example, 10 GPa or more and 100 GPa or less and/or 10 times or more and 100 times or less the first resin layer 10a. In addition, the first inorganic insulating layer 11a is set to, for example, 0 ppm/° C. or more and 10 ppm/° C. or less in coefficients of thermal expansion in the thickness direction and the planar direction thereof, and, for example, 0.0001 or more and 0.001 or less in the dielectric loss tangent.

The first inorganic insulating layer 11a can be formed of the above inorganic insulating material, and, among them, silicon oxide is desirably used from the viewpoint of a low dielectric loss tangent and a low coefficient of thermal expansion.

In addition, in the embodiment, the first inorganic insulating layer 11a is formed of an inorganic insulating material in an amorphous state. Since the anisotropy of the coefficient of thermal expansion, which is caused by the crystalline structure, can be reduced by an inorganic insulating material in an amorphous state more than an inorganic insulating material in a crystalline state, when the circuit board 3 is heated and then cooled, it is possible to make the first inorganic insulating layer 11a shrink more evenly in the thickness direction and the planar direction thereof, and to reduce cracking that occurs in the first inorganic insulating layers 11a.

As the inorganic insulating material in an amorphous state, for example, an inorganic insulating material including 90% by weight or more of silicon oxide can be used, and, among them, an inorganic insulating material including 99% by weight or more and less than 100% by weight of silicon oxide is desirably used. In a case in which an inorganic insulating material including 90% by weight or more and less than 100% by weight of silicon oxide is used, the inorganic insulating material may include inorganic insulating materials, such as aluminum oxide, titanium oxide, magnesium oxide, and zirconium oxide, in addition to silicon dioxide. Meanwhile, in the inorganic insulating material in an amorphous state, the region of crystalline phases is set to account for, for example, less than 10% by volume, and desirably less than 5% by volume.

Here, the volume proportion of the crystalline phase region in silicon oxide is measured as follows. Firstly, a plurality of comparative samples including different ratios of 100%-crystallized sample powder and amorphous powder are produced, and the comparative samples are measured by an X-ray diffraction method, thereby producing a calibration curve showing the relative relationship between the measured values and the volume proportion of the crystalline phase region. Next, an investigation sample, which is a measurement subject, is measured by the X-ray diffraction method, the measured value and the calibration curve are compared, and the volume proportion of the crystalline phase region is computed from the measured value, thereby measuring the volume proportion of the crystalline phase region in the investigation sample.

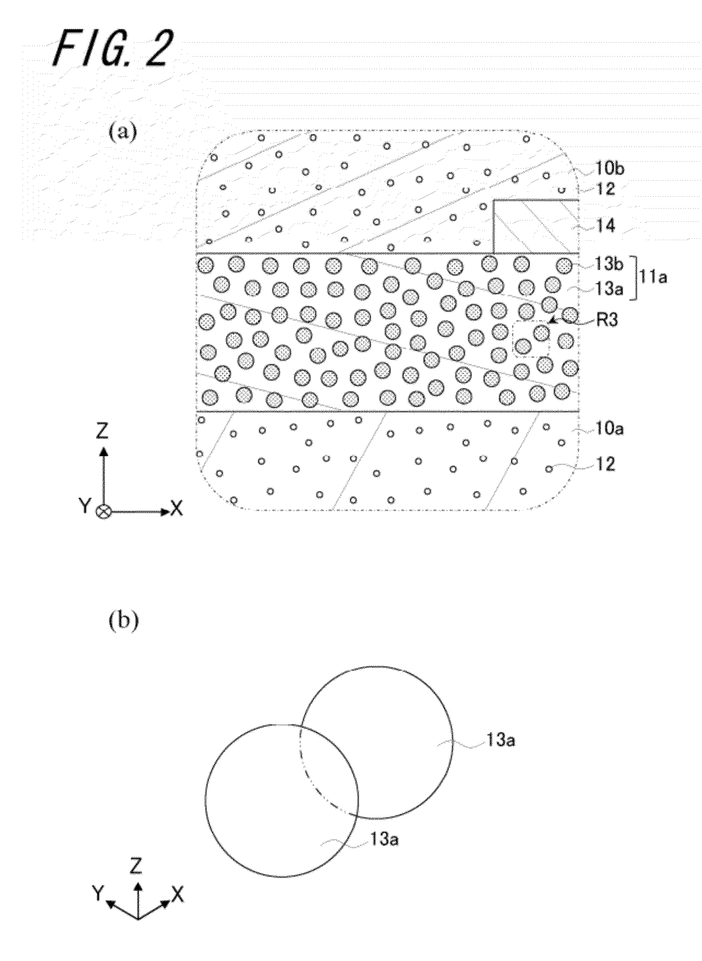

As shown in FIG. 2A, the first inorganic insulating layer 11a as described above includes a plurality of first inorganic insulating particles 13a and a plurality of second inorganic insulating particles 13b that have a larger particle diameter than that of the first inorganic insulating particles 13a. The plurality of first inorganic insulating particles 13a and the plurality of second inorganic insulating particles 13b can be formed of, for example, the inorganic insulating material as described above, such as silicon oxide, aluminum oxide, boron oxide, magnesium oxide, calcium oxide, or the like. In addition, the first and second inorganic insulating layers 11a and 11b include 20% by volume or more and 90% by volume or less of the first inorganic insulating particles 13a with respect to the total volume of the first inorganic insulating particles 13a and the second inorganic insulating particles 13b, and 10% by volume or more and 80% by volume or less of the second inorganic insulating particles 13b with respect to the above total volume.

The particle diameter of the first inorganic insulating particles 13a is set to 3 nm or more and 110 nm or less, and, as shown in FIG. 2B, the first inorganic insulating particles are connected to each other so as to densely form the inside of the first inorganic insulating layer 11a.

In addition, the particle diameter of the second inorganic insulating particles 13b is set to 0.5 μm or more and 5 μm or less, and the second inorganic insulating particles are connected with the first inorganic insulating particles 13a so as to be connected to each other via the first inorganic insulating particles 13a.

Here, the first inorganic insulating particles 13a and the second inorganic insulating particles 13b are confirmed by observing a polished surface or ruptured surface of the first inorganic insulating layer 11a using a field emission scanning electron microscope. In addition, the percentage by volume of the first inorganic insulating particles 13a and the second inorganic insulating particles 13b are computed as follows. Firstly, a polished surface of the first inorganic insulating layer 11a is photographed using a field emission scanning electron microscope. Next, the area proportions (% by area) of the first inorganic insulating particles 13a and the second inorganic insulating particles 13b are measured from the photographed image using an image analysis apparatus or the like. Additionally, an average value of the measured values is computed so as to compute the percentage by volume of the first and second inorganic insulating particles 13a and 13b. In addition, the particle diameters of the first inorganic insulating particles 13a and the second inorganic insulating particles 13b are measured by observing a polished surface or ruptured surface of the inorganic insulating layer 11 using a field emission scanning electron microscope, photographing a cross section that is enlarged so as to include 20 particles to 50 particles, and measuring the largest size of each particle on the photographed enlarged cross section.

In addition, the base 7 is provided with through holes that penetrate the base 7 in the thickness direction, and have, for example, a columnar shape having a diameter of 0.1 mm or more and 1 mm or less. Inside the through hole, the through hole conductor 8 that electrically connects the circuit layers 6 on the top and bottom of the core substrate 5 is formed along the inner wall of the through hole in a tubular shape. The through hole conductor 8 can be formed of a conductive material, for example, copper, silver, gold, aluminum, nickel, chromium, or the like, and the coefficient of thermal expansion is set to, for example, 14 ppm/° C. or more and 18 ppm/° C. or less.

In the hollow portion of the through hole conductor 8 formed in a tubular shape, an insulating body 9 is formed in a columnar shape. The insulating body 9 can be formed of a resin material, for example, a polyimide resin, an acryl resin, an epoxy resin, a cyanate resin, a fluororesin, a silicone resin, a polyphenylene ether resin, a bismaleimide triazine resin, or the like.

(Circuit Layer)

Meanwhile, the pair of circuit layers 6 are formed on the top and bottom surfaces of the core substrate 5 as described above.

Of the pair of circuit layers 6, one circuit layer 6 is connected to the electronic component 2 via a solder 3, and the other circuit layer 6 is connected to an external circuit board (not shown) via a joining material (not shown).

Each of the circuit layers 6 includes a plurality of the second resin layers 10b, a plurality of second inorganic insulating layers 11b, a plurality of conductive layers 14, a plurality of via holes, and a plurality of via conductors 15. The conductive layer 14 and the via conductor 15 are electrically connected with each other, and constituted by grounding wires, power supply wires, and/or signal wires.

The second resin layer 10b has a function of an insulating member that prevents short circuiting of the conductive layers 14. The second resin layer 10b can be formed of a thermosetting resin, for example, an epoxy resin, a bismaleimide triazine resin, a cyanate resin, a polyphenylene ether resin, a wholly aromatic polyamide resin, a polyimide resin, or the like.

The second resin layer 10b is set to, for example, 3 μm or more and 30 μm or less in thickness, and, for example, 0.2 GPa or more and 20 GPa or less in Young's modulus. In addition, the second resin layer 10b is set to, for example, 0.01 or more and 0.02 or less in dielectric loss tangent, and, for example, 20 ppm/° C. or more and 50 ppm/° C. or less in coefficients of thermal expansion in the thickness direction and the planar direction thereof.

In addition, in the embodiment, the second resin layer 10b contains the second filler 12 composed of a number of second filler particles that are formed of an inorganic insulating material. The second filler 12 can be formed of the same material as for the first filler 12, and it is possible to reduce the coefficient of thermal expansion of the second resin layer 10b and to enhance the stiffness of the second resin layer 10b.

The second inorganic insulating layer 11b is formed on the second resin layer 10b, and, similarly to the first inorganic insulating layer 11a included in the base 7 as described above, constituted by an inorganic insulating material that has a higher stiffness and lower coefficient of thermal expansion and dielectric loss tangent than those of a resin material, and thus the same effects of the first inorganic insulating layer 11a included in the base 7 as described above are exhibited.

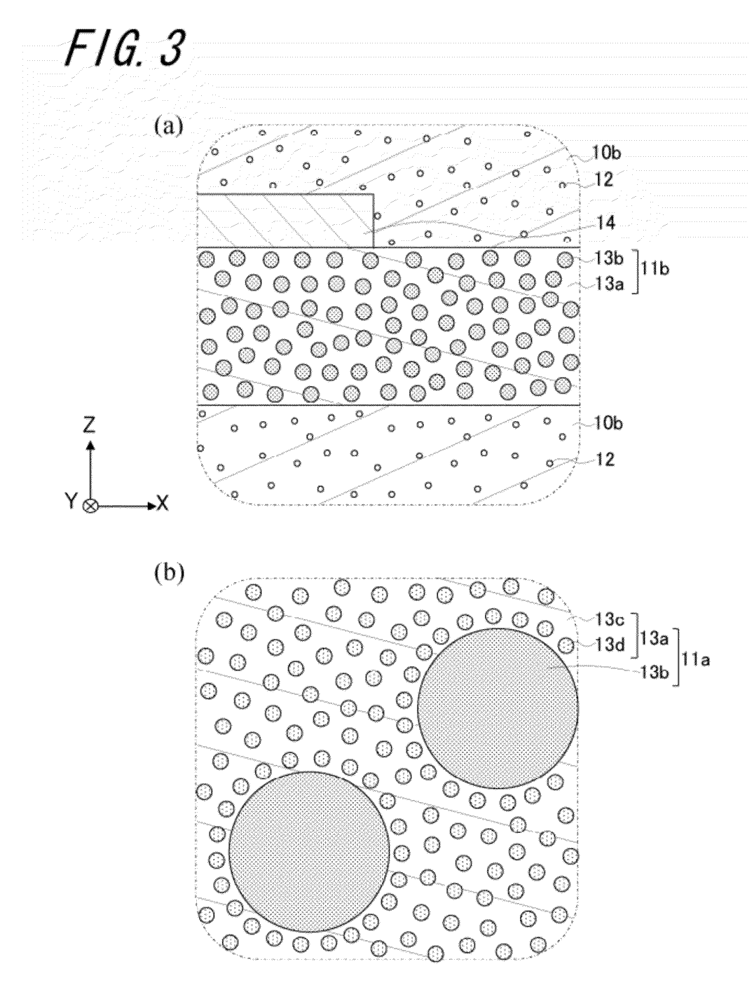

The thickness of the second inorganic insulating layer 11b is set to, for example, 3 μm or more and 30 μm or less and/or 0.5 time or more and 10 times or less (preferably 0.8 time or more and 1.2 times or less) the thickness of the second resin layer 10b. As shown in FIG. 3A, the other parts of the configuration are the same as in the configuration of the first inorganic insulating layer 11a as described above.

A plurality of the conductive layers 14 are formed on the second inorganic insulating layer 11b, and separated from each other in the thickness direction via the second resin layer 10b and the second inorganic insulating layer 11b. The conductive layer 14 can be formed of a conductive material, for example, copper, silver, gold, aluminum, nickel, chromium, or the like. In addition, the conductive layer 14 is set to, for example 3 μm or more and 20 μm or less in thickness, and, for example, 14 ppm/° C. or more and 18 ppm/° C. or less in coefficient of thermal expansion.

The via conductor 15 mutually connects the conductive layers 14 that are separated from each other in the thickness direction, and is formed in a columnar shape having a width that is narrowed toward the core substrate 5. The via conductor 15 can be formed of a conductive material, for example, copper, silver, gold, aluminum, nickel, chromium, or the like, and is set to, for example, 14 ppm/° C. or more and 18 ppm/° C. or less in coefficient of thermal expansion.

(First and Second Inorganic Insulating Particles)

Meanwhile, in a case in which, for example, a stress, such as a thermal stress or mechanical stress caused by the difference in the coefficient of thermal expansion between the electronic component 2 and the circuit board 3, is applied to the circuit board 3, there are cases in which the first inorganic insulating particles 13a are separated such that cracking occurs in the first and second inorganic insulating layers 11a and 11b.

Meanwhile, in the circuit board 3 of the embodiment, the first and second inorganic insulating layers 11a and 11b include the second inorganic insulating particles 13b that have a larger particle diameter than that of the first inorganic insulating particles 13a. Therefore, even when cracking occurs in the first and second inorganic insulating layers 11a and 11b, it is possible to inhibit extension of cracks due to the second inorganic insulating particles 13b having a large particle diameter, or bypass the cracks along the surface of the second inorganic insulating particles when the cracks reach the second inorganic insulating particles 13b. As a result, the cracks are suppressed from penetrating the first or second inorganic insulating layers 11a or 11b and reaching the conductive layers 14, it is possible to reduce breaking in the conductive layer 14 which originates from the cracks, and, furthermore, to obtain the circuit board 3 that is excellent in terms of the electrical reliability. In order to inhibit extension of the cracks and bypass the cracks, a case of the particle diameter of the second inorganic insulating particles being 0.5 μm or more is particularly preferred.

In addition, since the second inorganic insulating particles 13b have a large particle diameter, when the first and second inorganic insulating layers 11a and 11b are constituted by the second inorganic insulating particles only, it becomes difficult to dispose a number of second inorganic insulating particles around one second inorganic insulating particle, consequently, the contact area between the second inorganic insulating particles 13b becomes small, and the adhesion strength between the second inorganic insulating particles 13b is liable to be decreased. In contrast to the above, in the circuit board 3 of the embodiment, the first and second inorganic insulating layers 11a and 11b include not only the second inorganic insulating particles 13b having a large particle diameter but also the first inorganic insulating particles 13a having a small particle diameter, and the second inorganic insulating particles are joined via a plurality of the first inorganic insulating particles 13a disposed around the second inorganic insulating particle. Therefore, it is possible to increase the contact area between the second inorganic insulating particles and the first inorganic insulating particles, and to reduce separation between the second inorganic insulating particles 13b. Such an effect becomes particularly significant in a case in which the particle diameter of the first inorganic insulating particles is set to 110 nm or less.

Meanwhile, in the circuit board 3 of the embodiment, the particle diameter of the first inorganic insulating particles 13a is set to a small particle diameter of 3 nm or more and 110 nm or less. Since the particle diameter of the first inorganic insulating particles 13a is extremely small as such, the first inorganic insulating particles 13a are strongly connected to each other at a temperature lower than the crystallization onset temperature. As a result, the first and second inorganic insulating particles themselves are connected as the two are in an amorphous state, and the first and second inorganic insulating layers 11a and 11b turn into an amorphous state. Therefore, the anisotropy of the coefficient of thermal expansion of the first and second inorganic insulating layers 11a and 11b is decreased as described above. Meanwhile, when the particle diameter of the first inorganic insulating particles 13a is set to a small particle diameter of 3 nm or more and 110 nm or less, it is assumed that atoms in the first inorganic insulating particles 13a, particularly, atoms on the surface move actively, and therefore the first inorganic insulating particles 13a are strongly connected even at a low temperature lower than the crystallization onset temperature. Meanwhile, the crystallization onset temperature is a temperature at which an amorphous inorganic insulating material begins to crystallize, that is, a temperature at which the volume of the crystalline phase region increases.

In addition, in the embodiment, each of the second inorganic insulating particles 13b is coated with a plurality of first inorganic insulating particles 13a so that the second inorganic insulating particles 13b are separated from each other. As a result, contact between the second inorganic insulating particles 13b that have a low adhesion strength and are liable to be separated is prevented, separation of the second inorganic insulating particles 13b can be suppressed, and, furthermore, it is possible to reduce occurrence and extension of cracks caused by the second inorganic insulating particles.

The first inorganic insulating particles 13a and the second inorganic insulating particles 13b are desirably composed of the same material. As a result, in the first and second inorganic insulating layers 11a and 11b, it is possible to reduce cracks caused by the difference in the material characteristics of the first inorganic insulating particles 13a and the second inorganic insulating particles 13b. In addition, the first inorganic insulating particles 13a and the second inorganic insulating particles 13b are desirably composed of the same material as the first and second fillers 12. As a result, it is possible to further approximate the coefficients of thermal expansion of the first resin layer 10a and the second resin layer 10b to the coefficients of thermal expansion of the first and second inorganic insulating layers 11a and 11b.

The first inorganic insulating particles 13a desirably have a spherical shape as in the embodiment. As a result, since a number of the first inorganic insulating particles 13a become liable to fill voids among the second inorganic insulating particles, the volume of the voids among the first inorganic insulating particles 13a is reduced, the inside structures of the first and second inorganic insulating layers 11a and 11b can become dense, and it is possible to improve the stiffness of the first and second inorganic insulating layers 11a and 11b.

In addition, the second inorganic insulating particles 13b desirably have a curved surface shape as in the embodiment, and, furthermore, more desirably have a spherical shape. As a result, the surfaces of the second inorganic insulating particles 13b become smooth, a stress on the surface is dispersed, and it is possible to reduce occurrence of cracks in the first and second inorganic insulating layers 11a and 11b which originate from the surfaces of the second inorganic insulating particles 13b.

The second inorganic insulating particles 13b desirably have higher hardness than that of the first inorganic insulating particles 13a. In this case, when cracks reach the second inorganic insulating particles 13b, extension of the cracks into the second inorganic insulating particles 13b is reduced, and, furthermore, it is possible to reduce extension of cracks in the first and second inorganic insulating layers 11a and 11b. In addition, as described below, since the hardness of the second inorganic insulating particles 13b can be increased more easily than that of the first inorganic insulating particles 13a, it is possible to easily increase the stiffness of the first and second inorganic insulating layers 11a and 11b. Meanwhile, the hardness can be measured using a nano-indenter apparatus.

(Third and Fourth Inorganic Insulating Particles)

In addition, in the circuit board 3 of the embodiment, the first inorganic insulating particles 13a include third inorganic insulating particles 13c whose particle diameter is set to 3 nm or more and 15 nm or less, and fourth inorganic insulating particles 13d whose particle diameter is set to 35 nm or more and 110 nm or less as shown in FIG. 3B.

In this case, since the third inorganic insulating particles 13c are extremely small, the contact area between each of the third inorganic insulating particles 13c and other third inorganic insulating particles 13c or the fourth inorganic insulating particles 13d becomes large, and the third inorganic insulating particles or the third and fourth inorganic insulating particles can be strongly connected. In addition, even when the third inorganic insulating particles are separated, and cracks occur, extension of the cracks is favorably suppressed due to the fourth inorganic insulating particles 13d having a larger particle diameter than that of the third inorganic insulating particles 13c.

Adjacent fourth inorganic insulating particles 13d are desirably connected to each other via the third inorganic insulating particles 13c. As a result, the fourth inorganic insulating particles 13d can be strongly connected to each other via the third inorganic insulating particles 13c.

In addition, adjacent second inorganic insulating particles 13b and fourth inorganic insulating particles 13d are desirably connected to each other via the third inorganic insulating particles 13c. As a result, the second inorganic insulating particles 13b that have a low adhesion strength and are liable to be separated and the fourth inorganic insulating particles 13d can be strongly connected to each other due to the third inorganic insulating particles 13c. Furthermore, when each of the fourth inorganic insulating particles 13d is coated with a plurality of third inorganic insulating particles 13c so that the second and fourth inorganic insulating particles 11b and 11d are separated from each other, contact of each of the fourth inorganic insulating particles 13d is prevented, and the adhesion strength between the second inorganic insulating particles 13b and the fourth inorganic insulating particles 13d can be further improved.

The fourth inorganic insulating particles 13d are desirably composed of the same material as for the third inorganic insulating particles 13c. As a result, it is possible to reduce cracks caused by the difference in the material characteristics of the third inorganic insulating particles 13c and the fourth inorganic insulating particles 13d in the first and second inorganic insulating layers 11a and 11b.

In addition, the fourth inorganic insulating particles 13d desirably have a spherical shape. As a result, a stress on the surface of the fourth inorganic insulating particle 13d can be dispersed, and therefore it is possible to reduce occurrence of cracks in the first and second inorganic insulating layers 11a and 11b which originate from the surfaces of the fourth inorganic insulating particles 13d.

The first and second inorganic insulating layers 11a and 11b desirably include 10% by volume or more and 50% by volume or less of the third inorganic insulating particles 13c with respect to the total volume of the first inorganic insulating particles 13a and the second inorganic insulating particles 13b, and 10% by volume or more and 40% by volume or less of the fourth inorganic insulating particles 13d with respect to the total volume of the first inorganic insulating particles 13a and the second inorganic insulating particles 13b. When 10% by volume or more of the third inorganic insulating particles 13c are included, the third inorganic insulating particles 13c are disposed in gaps among the second inorganic insulating particles 13b and gaps among the second inorganic insulating particles 13b and the fourth inorganic insulating particles 13d at a high density, the third inorganic insulating particles 13c can be connected to each other, and occurrence and extension of cracks in such gaps can be reduced. In addition, when 10% by volume or more of the fourth inorganic insulating particles 13d are included, extension of cracks occurring in the gaps among the second inorganic insulating particles 13b can be favorably suppressed due to the fourth inorganic insulating particles 13d.

<Method for Manufacturing Circuit Board 3>

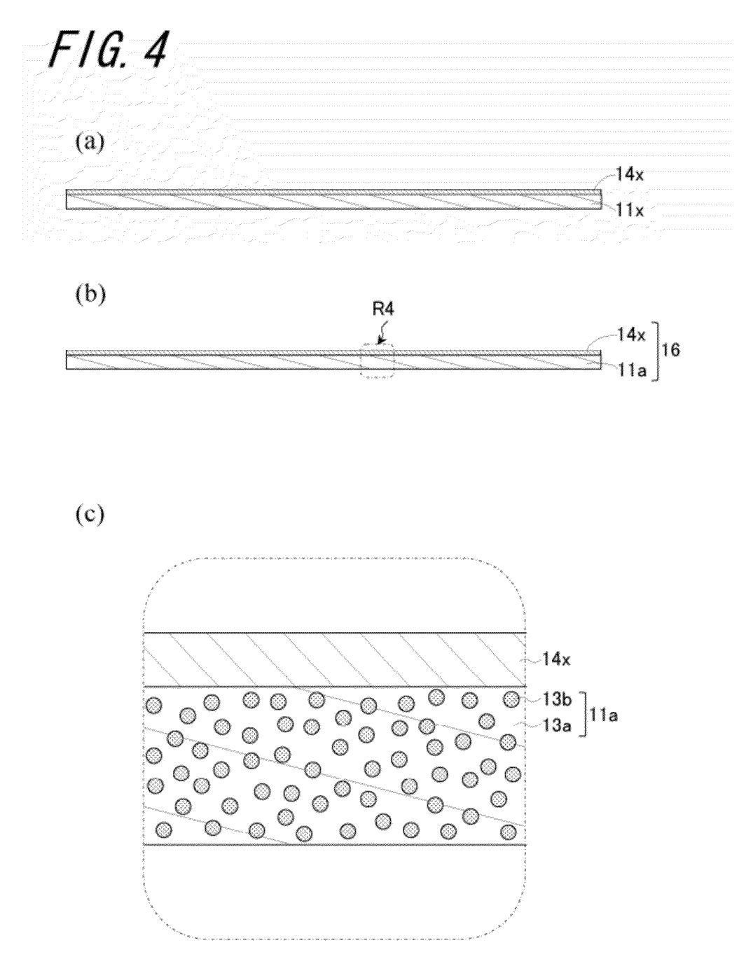

Next, a method for manufacturing the above circuit board 3 will be described based on FIGS. 4 to 7.

The method for manufacturing the circuit board 3 includes a production step of the core substrate 5 and a build-up step of the circuit layer 6.

(Production Step of Core Substrate 5)

(1) An inorganic insulating sol 11x having a solid content that includes the first inorganic insulating particles 13a and the second inorganic insulating particles 13b, and a solvent is prepared.

The inorganic insulating sol 11x includes, for example, 10% by volume or more and 50% by volume or less of the solid content and 50% by volume or more and 90% by volume or less of the solvent. Thereby, it is possible to maintain the viscosity of the inorganic insulating sol 11x at a low level and to maintain the productivity of the inorganic insulating layers formed of the inorganic insulating sol 11x at a high level.

The solid content of the inorganic insulating sol 11x includes, for example, 20% by volume or more and 90% by volume or less of the first inorganic insulating particles 13a, and 10% by volume or more and 80% by volume or less of the second inorganic insulating particles 13b. Furthermore, the solid content includes, for example, 10% by volume or more and 50% by volume or less of the third inorganic insulating particles 13c that compose the first inorganic insulating particles 13a, and 10% by volume or more and 40% by volume or less of the fourth inorganic insulating particles 13d that compose the first inorganic insulating particles 13a. Thereby, it is possible to effectively reduce occurrence of cracks in the first inorganic insulating layers 11a in a step (3) as described below.

Meanwhile, in a case in which the first inorganic insulating particles 13a are composed of silicon oxide, the first inorganic insulating particles can be produced by, for example, purifying a silicate compound, such as an aqueous solution of sodium silicate (water glass), and chemically precipitating silicon oxide. In this case, since the first inorganic insulating particles 14a can be produced under a low temperature condition, it is possible to produce the first inorganic insulating particles 14a in an amorphous state. In addition, the particle diameter of the first inorganic insulating particles 13a is adjusted by adjusting the precipitation time of silicon oxide, specifically, the longer the precipitation time, the larger the particle diameter of the first inorganic insulating particles 13a becomes. Therefore, it is preferable to mix two kinds of inorganic insulating particles formed with mutually different precipitation times of silicon oxide in order to produce the first inorganic insulating particles 13a including the third inorganic insulating particles 13c and the fourth inorganic insulating particles 13d.

Meanwhile, in a case in which the second inorganic insulating particles 13b are composed of silicon oxide, the second inorganic insulating particles can be produced by, for example, purifying a silicate compound, such as an aqueous solution of sodium silicate (water glass), spraying a solution having silicon oxide chemically precipitated therein to a flame, and heating the sprayed solution at 800° C. or higher and 1500° C. or lower while formation of aggregated substances is decreased. Therefore, since the second inorganic insulating particles 13b have a larger particle diameter than that of the first inorganic insulating particles 13a, formation of aggregates during high-temperature heating is easily reduced, the second inorganic insulating particles can be easily produced by high-temperature heating, and, furthermore, the hardness can be easily increased.

In addition, the heating time is desirably set to 1 second or more and 180 seconds or less when the second inorganic insulating particles 13b are produced. As a result, it is possible to suppress crystallization of the second inorganic insulating particles 13b and to maintain the amorphous state by shortening the heating time even in a case in which the solution is heated at 800° C. or higher and 1500° C. or lower.

Meanwhile, as the solvent included in the inorganic insulating sol 11x, an organic solvent including, for example, methanol, isopropanol, n-butanol, ethylene glycol, ethylene glycol monopropyl ether, methyl ethyl ketone, methyl isobutyl ketone, xylene, propylene glycol monomethyl ether, propylene glycol monomethyl ether acetate, dimethylacetamide, and/or a mixture of two kinds or more of those selected above can be used. Among them, an organic solvent including methanol, isopropanol or propylene glycol monomethyl ether is desirable. As a result, the inorganic insulating sol 11x can be uniformly applied, and therefore the solvent can be favorably evaporated in the step (3) as described below.

(2) Next, as shown in FIG. 4A, the inorganic insulating sol 11x is applied to one main surface of a metal foil 14x formed of a conductive material, such as copper, and the inorganic insulating sol 11x is formed in a lamellar shape.

The inorganic insulating sol 11x can be applied using, for example, a dispenser, a bar coater, a die coater, or screen printing. At this time, since the solid content of the inorganic insulating sol 11x is set to 50% by volume or less as described above, the viscosity of the inorganic insulating sol 11x is set to be low, and the flatness of the applied inorganic insulating sol 11x can be increased.

In addition, since the particle diameter of the first inorganic insulating particles 13a is set to 3 nm or more as described above, the viscosity of the inorganic insulating sol 11x is favorably reduced, and the flatness of the applied inorganic insulating sol 11x can be improved due to the above fact.

(3) Subsequently, the inorganic insulating sol 11x is dried, and the solvent is evaporated.

Here, the inorganic insulating sol 11x is shrunk in accordance with the evaporation of the solvent, and the solvent is included in gaps between the first and second inorganic insulating particles 13a and 13b, but not in the first and second inorganic insulating particles 13a and 13b themselves. Therefore, when the inorganic insulating sol 11x includes the second inorganic insulating particles 13b having a large particle diameter, regions filled with the solvent are decreased accordingly, and the amount of the inorganic insulating sol 11x shrunk during the evaporation of the solvent in the inorganic insulating sol 11x is decreased. That is, the shrinkage of the inorganic insulating sol 11x is restricted by the second inorganic insulating particles 13b. As a result, it is possible to reduce occurrence of cracking caused by the shrinkage of the inorganic insulating sol 11x. In addition, even when cracks occur, it is possible to hinder extension of the cracks via the second inorganic insulating particles 13b having a large particle diameter.

Furthermore, since the plurality of first inorganic insulating particles 13a include the fourth inorganic insulating particles 13d having a large particle diameter and the third inorganic insulating particles 13c having a small particle diameter, the shrinkage of the inorganic insulating sol 11x in the gaps among the second inorganic insulating particles 13b is also restricted by the fourth inorganic insulating particles 13d, and occurrence of cracks in the gaps among the second inorganic insulating particles 13b is further reduced.

The inorganic insulating sol 11x is dried by, for example, heating and air drying. The drying temperature is set to, for example, 20° C. or higher and lower than the boiling point of the solvent (in a case in which two kinds or more of solvents are included in a mixed state, the boiling point of a solvent having the lowest boiling point), and the drying time is set to, for example, 20 seconds or more and 30 minutes or less. As a result, boiling of the solvent is reduced, loss of the first and second inorganic insulating particles 13a and 13b due to the pressure of air bubbles generated during the boiling is suppressed, and the distribution of the particles can become more uniform.

(4) The solid content of the remaining inorganic insulating sol 11x is heated, and the first inorganic insulating layer 11a is formed using the inorganic insulating sol 11x. As a result, a laminate sheet 16 having the metal foil 14x and the first inorganic insulating layer 11a as shown in FIGS. 4B and 4C is produced.

Here, the inorganic insulating sol 11x of the embodiment has the first inorganic insulating particles 13a whose particle diameter is set to 110 nm or less. As a result, the first inorganic insulating particles 13a can be strongly connected to each other even when the heating temperature of the inorganic insulating sol 11x is a relatively low temperature, for example, a low temperature lower than the crystallization onset temperatures of the first inorganic insulating particles 13a and the second inorganic insulating particles 13b. Meanwhile, in a case in which a substance formed of silicon oxide is used as the first inorganic insulating particles 13a, the temperature at which the first inorganic insulating particles 13a can be strongly connected to each other is, for example, approximately 250° C. in a case in which the particle diameter of the first inorganic insulating particles 13a is set to 110 nm or less, and approximately 150° C. in a case in which the particle diameter is set to 15 nm or less. In addition, in a case in which the first and second inorganic insulating particles 13a and 13b are composed of silicon oxide, the crystallization onset temperatures are approximately 1300° C.

The heating temperature of the inorganic insulating sol 11x is desirably the boiling point of the solvent or higher in order to evaporate the remaining solvent. In addition, the heating temperature is desirably set to a temperature lower than the crystallization onset temperatures of the first inorganic insulating particles 13a and the second inorganic insulating particles 13b. In this case, it is possible to reduce the crystallization of the first inorganic insulating particles 13a and the second inorganic insulating particles 13b, and to increase the proportion of the amorphous state. As a result, it is possible to reduce shrinkage of the crystallized first inorganic insulating layers 11a due to phase transition, and to reduce occurrence of cracks in the first inorganic insulating layers 11a. Meanwhile, in a case in which the first and second inorganic insulating particles 13a and 13b are composed of silicon oxide, the inorganic insulating sol 11x is heated, for example, under the atmosphere with a temperature set to, for example, 100° C. or higher and lower than 600° C. and a time set to, for example, 0.5 hour or more and 24 hours or less. Meanwhile, in a case in which the heating temperature is 150° C. or higher, in order to suppress oxidation of the metal foil 14x, it is desirable to heat the inorganic insulating sol 11x under a vacuum, an inert atmosphere, such as argon, or a nitrogen atmosphere.

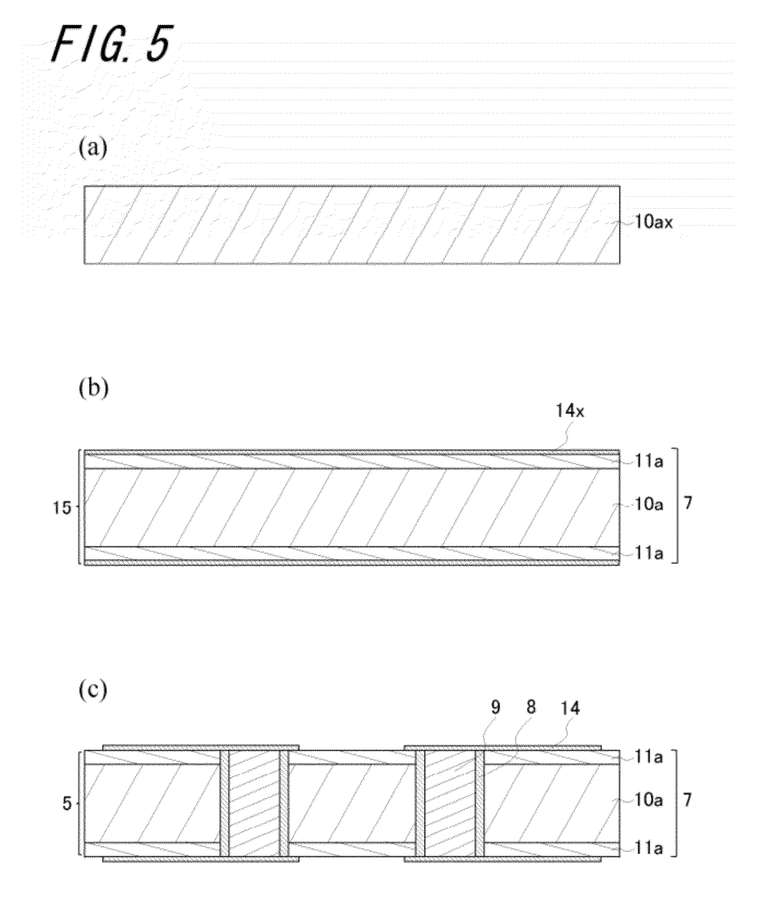

(5) A first resin precursor sheet 10ax as shown in FIG. 5A is prepared, and the laminate sheets 16 are laminated on the top and bottom surfaces of the first resin precursor sheet 10ax.

The first resin precursor sheet 10ax can be produced by, for example, laminating a plurality of resin sheets including an uncured thermosetting resin and a base member. Meanwhile, the uncured refers to a state of A-stage or B-stage according to ISO 472:1999.

The laminate sheets 16 are laminated so as to have the first inorganic insulating layer 11a interposed between the metal foil 14x and the first resin precursor sheet 10ax.

(6) Next, the first resin precursor sheet 10ax is cured by heating and pressurizing the laminated body in the vertical direction so as to form the first resin layer 10a as shown in FIG. 5B.

The heating temperature of the laminated body is set to the curing onset temperature or higher and lower than the thermal decomposition temperature of the first resin precursor sheet 10ax. Specifically, in a case in which the first resin precursor sheet is composed of an epoxy resin, a cyanate resin, a bismaleimide triazine resin, or a polyphenylene ether resin, the heating temperature is set to, for example, 170° C. or higher and 230° C. or lower. In addition, the pressure of the laminated body is set to, for example, 2 MPa or more and 3 MPa or less, and the heating time and the pressurizing time are set to, for example, 0.5 hour or more and 2 hours or less. Meanwhile, the curing onset temperature is a temperature at which a resin turns into a state of C-stage according to ISO 472:1999. In addition, the thermal decomposition temperature is a temperature at which the mass of a resin is decreased by 5% in thermogravimetric measurement according to ISO 11358:1997.

(7) As shown in FIG. 5C, the through hole conductors 8 that penetrate the base 7 in the thickness direction and the insulating bodies 9 inside the through hole conductors 8 are formed, and then the conductive layers 14 connected to the through hole conductors 8 are formed on the base 7.

The through hole conductor 8 and the insulating body 9 are formed as follows. Firstly, a plurality of through holes that penetrate the base 7 and the metal foil 14x in the thickness direction are formed by, for example, a drilling process, a laser processing, or the like. Next, a conductive material is coated on the inner wall of the through hole by, for example, electroless plating, vapor deposition, CVD, sputtering, or the like, thereby forming the cylindrical through hole conductor 8. Next, a resin material and the like are filled in the cylindrical through hole conductor 8 so as to form the insulating body 9.

In addition, the conductive layer 14 is formed by coating a metal layer composed of the same metallic material as for the metal foil 14x on the insulating body 9 and the through hole conductor 8 exposed through the through holes formed in the metal foil 14x by, for example, electroless plating, vapor deposition, CVD, sputtering, or the like, and, subsequently, patterning the metal foil 14x and/or the metallic layer using photolithography technique, etching, or the like. Meanwhile, the conductive layer 14 may be formed by firstly separating the metal foil 14x, then, forming the metallic layer on the base 7, and patterning the metallic layer.

The core substrate 5 can be produced in the above manner.

(Build-up Step of Circuit Layer 6)

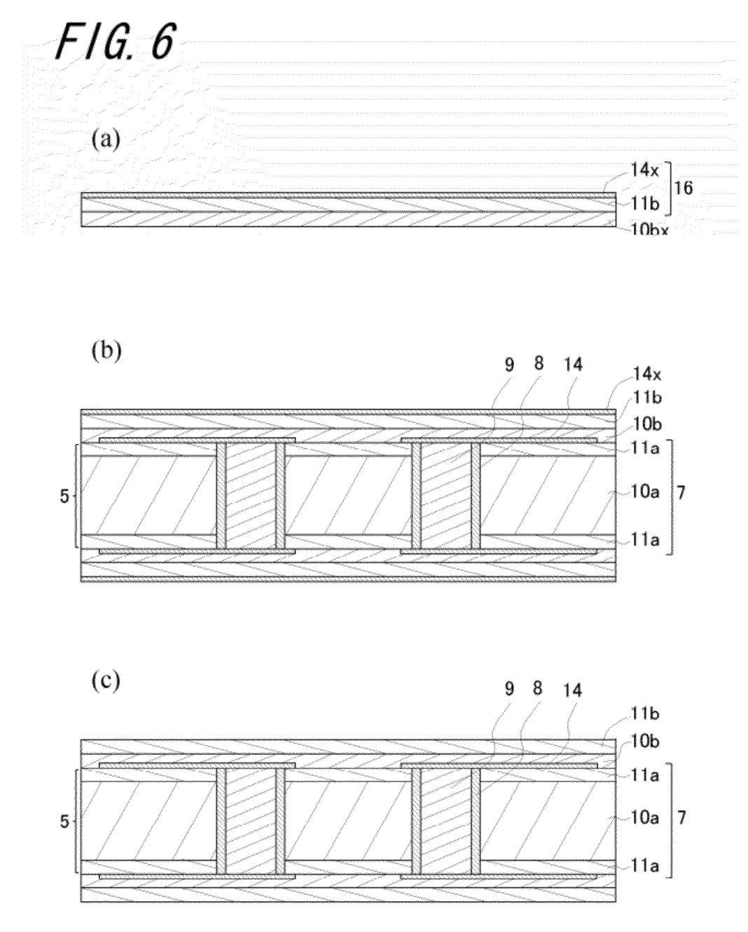

(8) After the second resin precursor sheet 10bx and the laminate sheet 16 having the second inorganic insulating layer 11b and the metal foil 14x are newly prepared, the laminate sheet 16 is laminated on the second resin precursor sheet 10bx as shown in FIG. 6A.

The second resin precursor sheet 10bx is formed of the uncured thermosetting resin as described above which composes the second resin layer 10b.

In addition, the laminate sheet 16 is placed on the second resin precursor sheet 10bx so as to have the second inorganic insulating layer 11b interposed between the second resin precursor sheet 10bx and the metal foil 14x.

(9) Next, the laminate sheets 16 are laminated on the top and bottom surfaces of the core substrate 5 respectively via the second resin precursor sheets 10bx.

(10) The laminated body of the core substrate 5 and the laminate sheet 16 is heated and pressurized in the vertical direction so as to cure the thermosetting resin of the second resin precursor sheet 10bx and make the second resin precursor sheet 10bx into the second resin layer 10b as shown in FIG. 6B.

Meanwhile, the laminate can be heated and pressurized in the same manner as, for example, in the step (6).

(11) As shown in FIG. 6C, the metal foil 14x is separated from the second inorganic insulating layer 11b by etching in which, for example, a liquid mixture of sulfuric acid and hydrogen peroxide, a ferric chloride solution, a copper chloride solution, or the like is used.

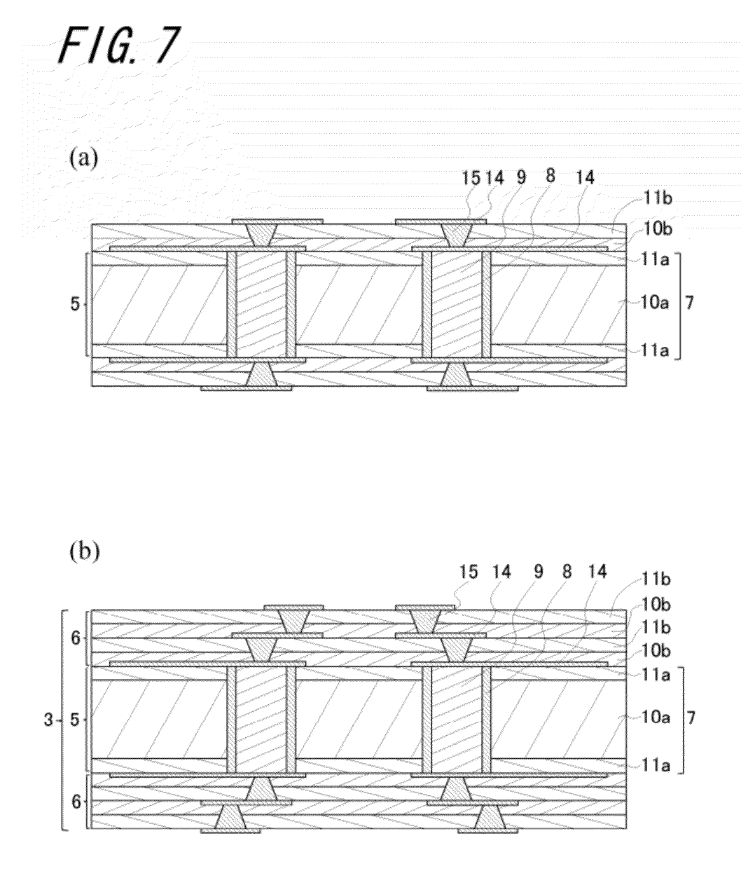

12) As shown in FIG. 7A, the via conductors 15 that penetrate the second resin layer 10b and the second inorganic insulating layer 11b in the thickness direction thereof are formed, and the conductive layers 14 are formed on the second inorganic insulating layer 11b.

The via conductor 15 and the conductive layer 14 are formed specifically as follows. Firstly, the via holes that penetrate the second resin layer 10b and the second inorganic insulating layer 11b are formed using, for example, a YAG laser apparatus or a carbon dioxide laser apparatus. Next, the via conductor 15 is formed in the via hole by, for example, the semi additive method, the subtractive method, the full additive method, or the like, and a conductive material is coated on the second inorganic insulating layer 11b so as to form the conductive layer 14. Meanwhile, the conductive layer 14 may be formed by patterning the metal foil 13 without separating the metal foil 13 in the step (11).

(13) As shown in FIG. 7B, the circuit layers 6 are formed on the top and bottom of the core substrate 5 by repeating the steps (8) to (12). Meanwhile, the circuit layer 6 can be multilayered by repeating the present steps.

The circuit board 3 can be produced as described above. Meanwhile, the electronic component 2 is flip-mounted on the produced circuit board 3 via the bumps 4, whereby a mounting structure 1 as shown in FIG. 1 can be produced.

Meanwhile, the electronic component 2 may be electrically connected with the circuit board 3 by wire bonding, or may be housed in the circuit board 3.

### Second Embodiment

Next, the circuit board according to a second embodiment of the invention will be described in detail based on the accompanying drawings. Meanwhile, with respect to the same configuration as in the first embodiment as described above, description thereof may be omitted.

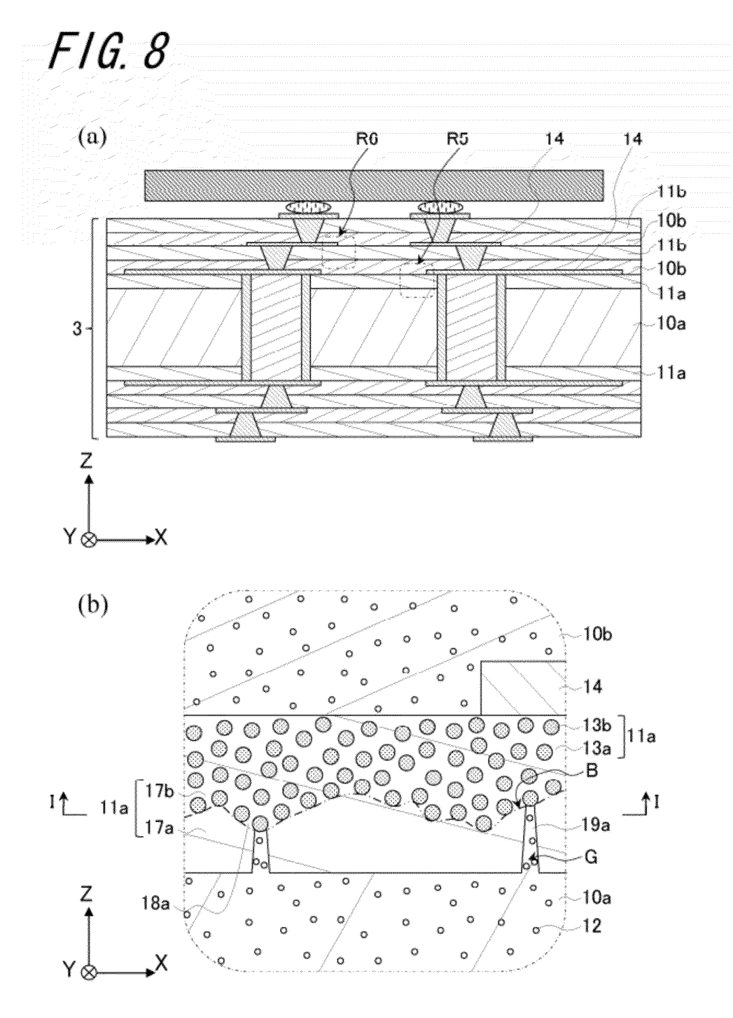

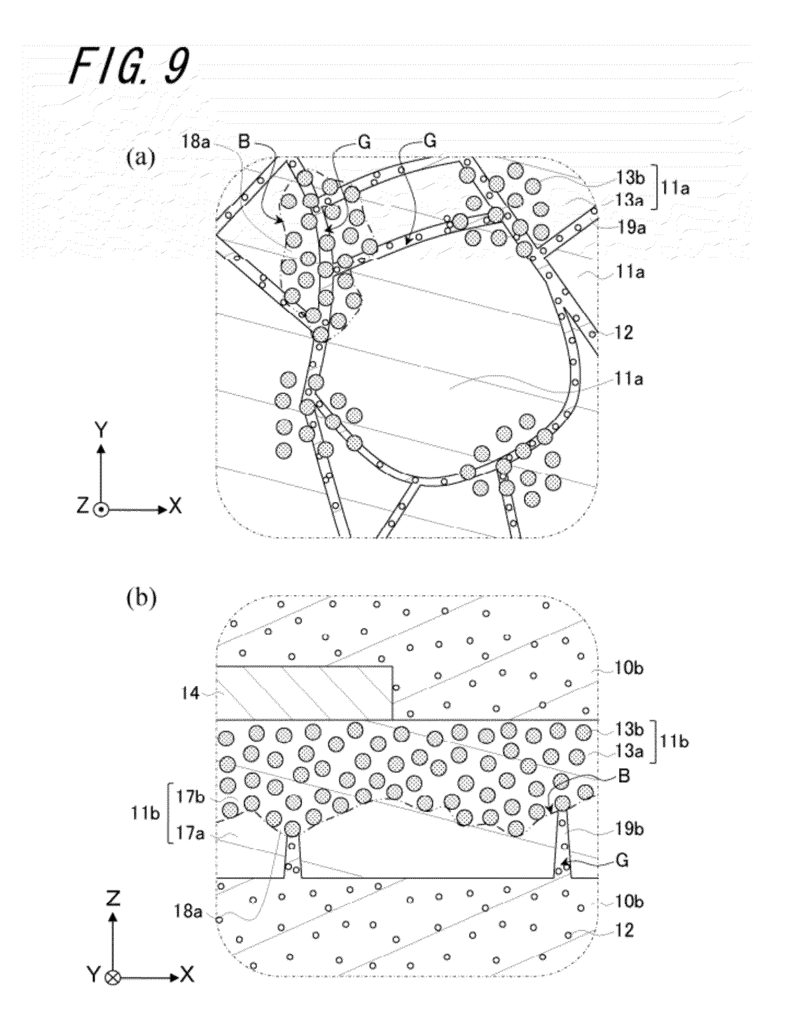

Unlike the first embodiment, in the second embodiment, as shown in FIGS. 8A, 8B, and 9B, the first inorganic insulating layer 11a has a first inorganic insulating portion 17a located on one main surface side (on the first resin layer 10a side) and a second inorganic insulating portion 17b located on the other surface side (on the conductive layer 14 side), and the second inorganic insulating portion 17b includes the second inorganic insulating particles 13b more than the first inorganic insulating portion 17a. As a result, in a case in which a stress is applied to the circuit board 3, the second inorganic insulating particles 13b suppress growth of cracks in the second inorganic insulating portion 17b in the first inorganic insulating layer 11a, breaking in the conductive layer 14 which originates from such cracks can be reduced, and it is possible to produce the circuit board 3 that is excellent in terms of the electrical reliability.

Meanwhile, in the embodiment, the first inorganic insulating portion 17a does not have the second inorganic insulating particles 13b, and the second inorganic insulating portion 17b has the second inorganic insulating particles 13b. In this case, a boundary B between the first inorganic insulating portion 17a and the second inorganic insulating portion 17b is constituted by the surfaces of the second inorganic insulating particles 13b located closest to one main surface of the inorganic insulating layer 11 in the thickness direction thereof.

The first inorganic insulating portion 17a is set to, for example, 10% or more and 65% or less of the first and second inorganic insulating layers 11a and 11b in thickness. In addition, the second inorganic insulating portion 17b is set to, for example, 35% or more and 90% or less of the first and second inorganic insulating layers 11a and 11b in thickness, and includes, for example, 55% by volume or more and 75% by volume or less of the second inorganic insulating particles. Meanwhile, the thicknesses of the first inorganic insulating portion 17a and the second inorganic insulating portion 17b are measured by calculating average values of the thicknesses in a field emission scanning electron microscope photograph of a surface that is cut in the thickness direction thereof.

In addition, in the embodiment, the second inorganic insulating portion 17b has first protruding portions 18a that protrude toward the first inorganic insulating portion 17a and have a plurality of the second inorganic insulating particles 11a. Meanwhile, the first protruding portion 18a has a length in the protrusion direction set to, for example, 2.5 μm or more and 10 μm or less, and a length in the width direction set to, for example, 5 μm or more and 30 μm or less.

Furthermore, as shown in FIG. 8B, the first inorganic insulating layer 11a has groove portions G that have an opening only on one main surface side and extend along the thickness direction, and the groove portion G is filled with a part of the first resin layer 10a (first filled portion 19a). As a result, when a stress is applied to the circuit board 3, the first filled portion 19a having low Young's modulus relaxes the stress applied to the first inorganic insulating layer 11a in the groove portion G, and therefore cracks in the first inorganic insulating layer 11a can be reduced.

In addition, since the groove portion G has an opening only on one main surface side of the first inorganic insulating layer 11a, and the conductive layers 14 are formed on the other main surface side of the first inorganic insulating layer 11a at which no opening of the groove portion G is present, it is possible to reduce breaking in the conductive layers 14 which is caused by separation of the first filled portion 19a.

In addition, since the coefficient of thermal expansion of the first filled portion 19a disposed in the groove portion G is higher than that of an inorganic insulating material, it is possible to decrease the coefficient of thermal expansion on the other main surface side of the first inorganic insulating layer 11a so as to approximate the coefficient of thermal expansion of the conductive layer 14, and to increase the coefficient of thermal expansion on one main surface side of the first inorganic insulating layer 11a so as to approximate the coefficient of thermal expansion of the first resin layer 10a.

In addition, the first resin layer 10a is in contact with one main surface of the first inorganic insulating layer 11a, and the first filled portion is disposed in the groove portion G. As a result, the adhesion strength between the first resin layer 10a and the first inorganic insulating layer 11a is increased due to the anchor effect, and it is possible to reduce separation between the first resin layer 10a and the first inorganic insulating layer 11a.

The bottom portion of the groove portion G is desirably in contact with the second inorganic insulating particles 13b, particularly the second inorganic insulating particles 13b that compose the boundary B between the second inorganic insulating portion and the first inorganic insulating portion. In this case, cracks caused by separation of the first filled portions 19a are not easily extended in the first inorganic insulating layers 11a compared to a case in which there are gaps between the bottom portion of the groove portion G and the second inorganic insulating particles 13b. In addition, in this case, the first filled portion 19a in the groove portion G is desirably attached to the second inorganic insulating particles 13b.

In addition, the groove portions G are formed so as to extend in plural different directions in a plan view as shown in FIG. 9A, and the width of the groove portion that crosses orthogonally in the longitudinal direction thereof is set to, for example, 0.3 μm or more and 5 μm or less. When the width of the groove portion G is set to 0.3 μm or more, the first filled portion 19a can be easily disposed in the groove portion G. In addition, when the width of the groove portion G is set to 5 μm or less, the proportion of the first inorganic insulating layer 11a with respect to the total of the first inorganic insulating layer 11a and the first filled portion 19a can be increased, and it is possible to enhance the stiffness of the first inorganic insulating layer 11a and to reduce the coefficient of thermal expansion and the dielectric loss tangent.

In addition, the width of the groove portion G is desirably decreased from one main surface side of the first inorganic insulating layer toward the second inorganic insulating portion 17b. As a result, the amount of the first filled portion 19a is decreased toward the second inorganic insulating portion 17b, and it is possible to decrease the coefficient of thermal expansion of the first inorganic insulating portion 17a in the vicinity of the boundary B between the first inorganic insulating portion 17a and the second inorganic insulating portion 17b so as to approximate the coefficient of thermal expansion of the second inorganic insulating portion 17b, and to increase the coefficient of thermal expansion of the first inorganic insulating portion 17a in one main surface side of the first inorganic insulating layer 11a so as to approximate the coefficient of thermal expansion of the first resin layer 10a. Meanwhile, the width of the bottom portion of the groove portion G is desirably set to 0.5 time or more and 0.97 time or less the opening portion of the groove portion G.

Meanwhile, as shown in FIG. 9B, the second inorganic insulating layer 11b, similarly to the first inorganic insulating layer 11a disposed on the first resin layer 10a as described above, has a groove portion G that has an opening only on one main surface side of the first inorganic insulating layer 10 and extends along the thickness direction thereof, and a second filled portion 19b, which is a part of the second resin layer 10b, is disposed in the groove portion G. The second filled portion 19b desirably has the same configuration as that of the first filled portion 19a as described above.

The first and second inorganic insulating layers 11a and 11b of the embodiment as described above can be formed in the following manner.

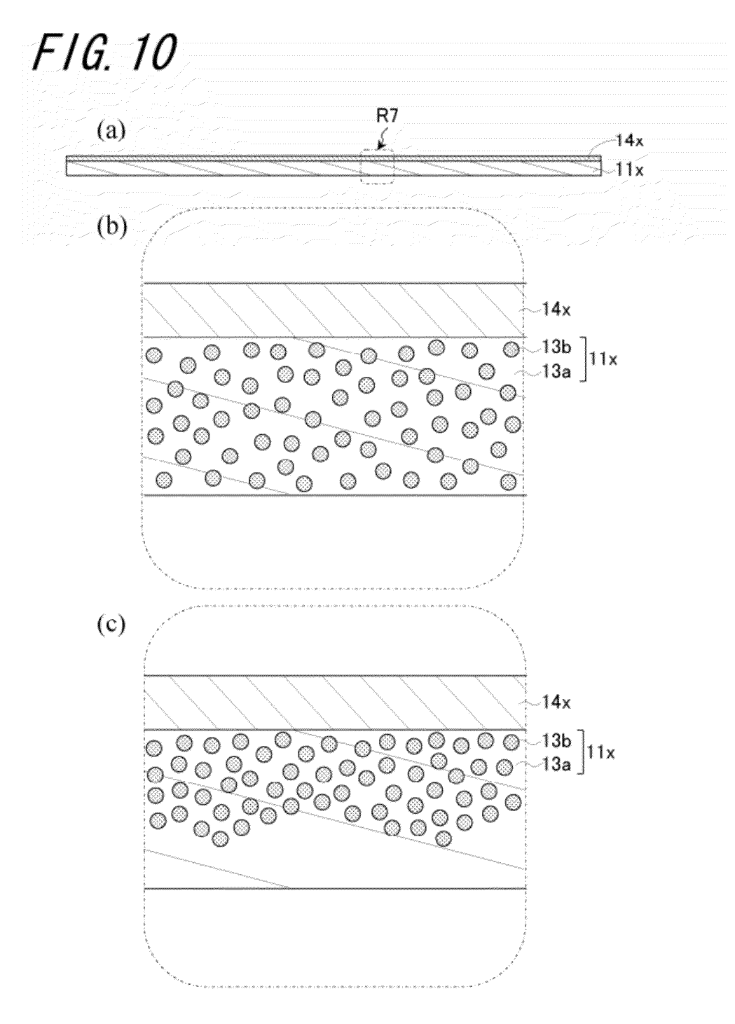

(1A) As shown in FIGS. 10A to 10C, before the step (3) in the first embodiment, the second inorganic insulating particles 13b in the inorganic insulating sol 11x are made to settle on the metal foil 14x side of the first inorganic insulating layer 11a by gravity and/or a centrifugal force, and a number of the second inorganic insulating particles 13b are contained on the metal foil 14x side of the first inorganic insulating layer 11a.

The settlement can be carried out by, for example, disposing the inorganic insulating sol 11x in a closed container, and maintaining a state in which the inorganic insulating sol 11x is not easily dried so as to hold the viscosity of the inorganic insulating sol 11x at a low level for a long period of time.

In addition, the settlement time of the second inorganic insulating particles 13b is set to, for example, 3 minutes or more and 30 minutes or less in the case of settlement by gravity. In addition, in a case in which the second inorganic insulating particles are made to settle using a centrifugal force, the settlement time can be shortened further.

By appropriately adjusting conditions during the settlement of the second inorganic insulating particles 13b, such as the density and temperature of solvent vapor in the closed container, the viscosity of the inorganic insulating sol 11x, the centrifugal force, and the settlement time, the settlement amount of the second inorganic insulating particles 13b can be adjusted, and the thicknesses of the first and second inorganic insulating portions can be controlled. Particularly, the settlement time and the viscosity of the inorganic insulating sol 11x are liable to affect the settlement amount of the second inorganic insulating particles 13b, as the settlement time is increased, the settlement amount of the second inorganic insulating particles 13b is increased, and, as the viscosity of the inorganic insulating sol 11x is decreased, the settlement amount of the second inorganic insulating particles 13b is increased.

Meanwhile, in a case in which the settlement amount of the second inorganic insulating particles 13b is increased, the first inorganic insulating particles 13a also settle on the metal foil 14x side, and therefore the density of the first inorganic insulating particles 13a can be increased on the metal foil 14x side.

In addition, in order to form the above first protruding portions 18a, it is preferable to make the application amount of the inorganic insulating sol 11x uneven so as to form protrusions and recesses on the surface.

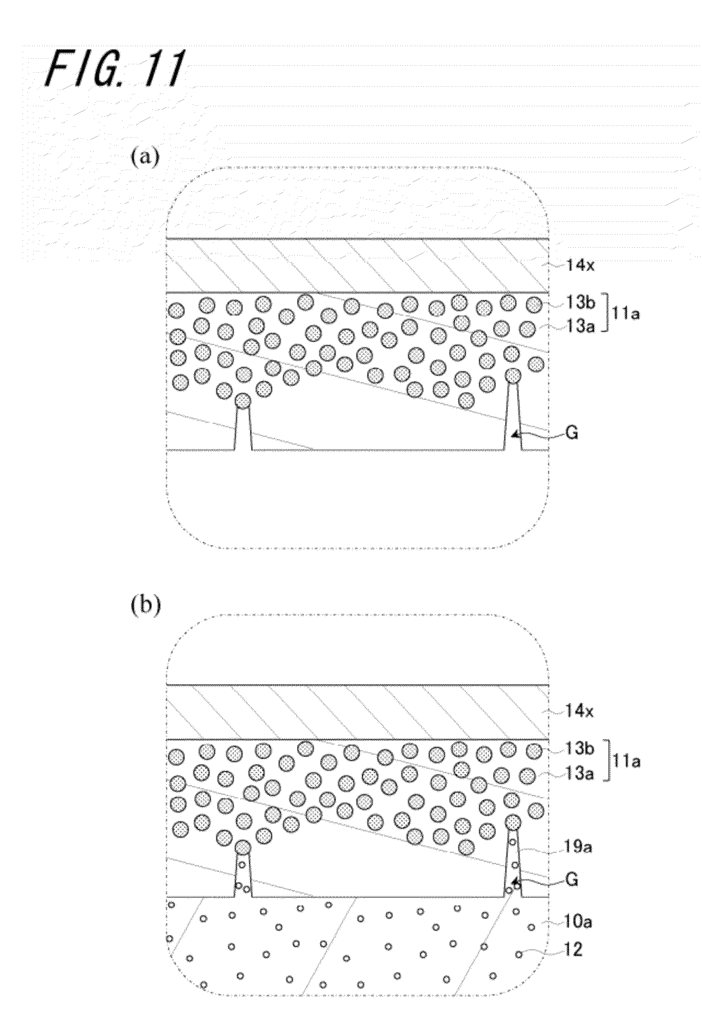

(2A) As shown in FIG. 11A, similarly to the step (3) in the first embodiment, the solvent in the inorganic insulating sol 11x is evaporated.

Here, in the step (1A), since the first and second inorganic insulating layers include a number of the second inorganic insulating particles 13b on the metal foil 14x side, when the solvent of the inorganic insulating sol 11x is evaporated, the shrinkage amount of the first inorganic insulating layer 11a in one planar direction becomes larger on one main surface side than on the other main surface side. As a result, it is possible to form groove portions G that extend along the thickness direction in regions on one main surface side of the first inorganic insulating layer 11a. In the groove portion G, the width is easily decreased from the opening portion of the groove G toward the bottom portion. Meanwhile, even when the groove portion G further extends toward the other main surface side, if the groove portion G reaches the second inorganic insulating particles 13b, the extension is suppressed due to the second inorganic insulating particles 13b. As a result, the bottom portion of the groove portion G is in contact with the second inorganic insulating particles 13b.

(3A) As shown in FIG. 11B, similarly to the step (6) in the first embodiment, when a laminate of the first resin precursor sheet and the laminate sheet is heated and pressurized, a part of the first resin precursor sheet is filled in the groove portion G. In addition, likewise, similarly to the step (10) in the first embodiment, when a laminate of the second resin precursor sheet and the laminate sheet is heated and pressurized, a part of the second resin layer 10b is filled in the groove portion G.

The circuit board 3 of the embodiment can be formed in the above manner.

### Third Embodiment

Next, a mounting structure including the circuit board according to a third embodiment of the invention in detail will be described based on the accompanying drawings. Meanwhile, with respect to the same configuration as in the first embodiment and the second embodiment as described above, description thereof will be omitted.

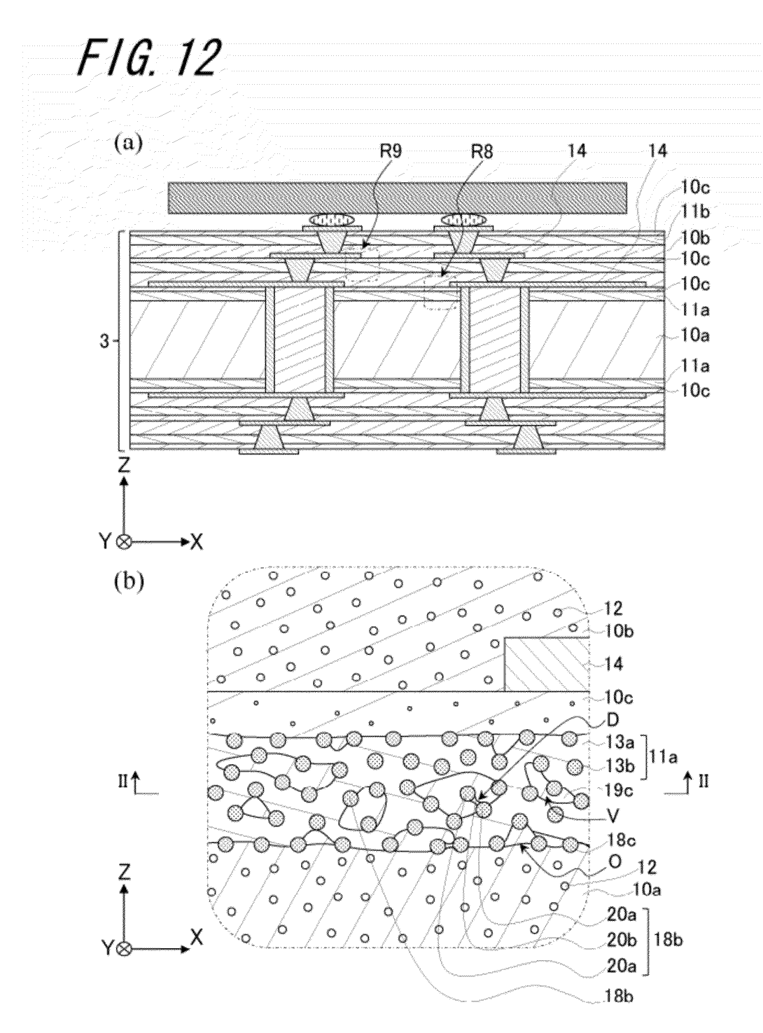

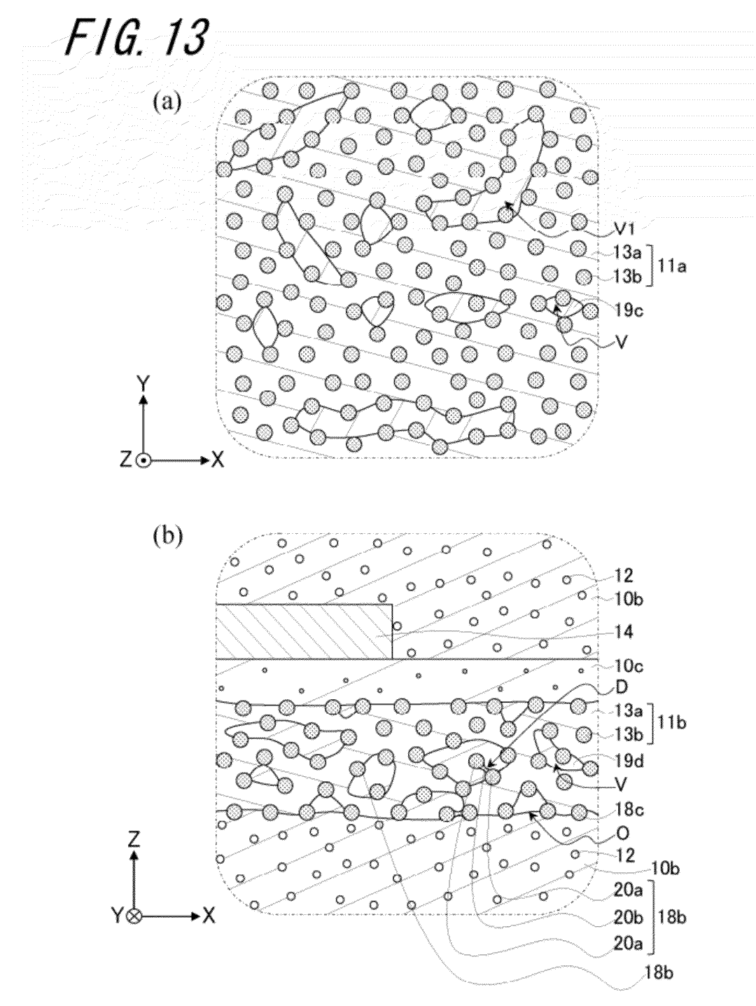

Unlike the first embodiment and the second embodiment, in the third embodiment, the circuit board 3 has third resin layers 10c interposed between the first and second inorganic insulating layers 11a and 11b and the conductive layers 14 as shown in FIGS. 12A, 12B, and 13B.

The third resin layer 10c has a function of relaxing a thermal stress between the first and second inorganic insulating layers 11a and 11b and the conductive layers 14 and a function of reducing breaking in the conductive layers 14 which is caused by cracks in the first and second inorganic insulating layers 11a and 11b, has one main surface in contact with the first and second inorganic insulating layers 11a and 11b and the other main surface in contact with the conductive layers 14, and includes, for example, a resin portion and a filler coated with the resin portion.

In addition, the third resin layer 10c is set to, for example, 0.1 μm or more and 5 μm or less in thickness, for example, 0.05 GPa or more and 5 GPa or less in Young's modulus, for example, 20 ppm/° C. or more and 100 ppm/° C. or less in coefficients of thermal expansion in the thickness direction and the planar direction thereof, and, for example, 0.005 or more and 0.02 or less in dielectric loss tangent.

Like the embodiment, the third resin layer 10c is desirably set to be small in the thickness and low in the Young's modulus, compared to the first resin layer 10a, the second resin layer 10b, and the first and second inorganic insulating layers 11a and 11b. In this case, the third resin layer 10c that is thin and easily deformed elastically alleviates a thermal stress caused by the difference in the thermal expansion amount between the first and second inorganic insulating layers 11a and 11b and the conductive layers 14. Therefore, the first and second inorganic insulating layers 11a and 11b suppress separation of the conductive layers 14, breaking in the conductive layers 14 can be reduced, and the circuit board 3 that is excellent in terms of the electrical reliability can be produced.

The resin portion included in the third resin layer 10c forms the main portion of the third resin layer 10c, and is composed of, for example, a resin material, such as an epoxy resin, a bismaleimide triazine resin, a cyanate resin, or a polyimide resin.

The third filler included in the third resin layer 10c has a function of increasing the flame resistance of the third resin layer 10c or a function of suppressing adhesion of the laminate sheets while being handled as described below, and can be formed of, for example, an inorganic insulating material, such as silicon oxide. The third filler is set to, for example, 0.05 μm or more and 0.7 μm or less in particle diameter, and, for example, 0% by volume or more and 10% by volume or less in content in the third resin layer 10c.

Meanwhile, unlike the first embodiment and the second embodiment, in the third embodiment, the first inorganic insulating layer 11a disposed on the first resin layer 10a has a plurality of voids V surrounded with the first inorganic insulating particles 13a and the second inorganic insulating particles 13b in a cross section that is cut along the thickness direction as shown in FIGS. 12B and 13A, and the void V is filled with a part of the first resin layer 10a (a third filled portion 19c). As a result, even when a stress is applied to the circuit board 3, and cracks occur in the first inorganic insulating layers 11a, extension of the cracks can be hindered or bypassed by the third filled portions 19c. Therefore, it is possible to reduce breaking in the conductive layers 14 which is caused by the cracks, and to produce the circuit board 3 that is excellent in terms of the electrical reliability.

In addition, since the third filled portion 19c includes a larger amount of a resin material than that of the first inorganic insulating layer 11a, the resin material having lower Young's modulus than that of the inorganic insulating material, in a case in which a stress is applied to the circuit board 3, it is possible to relax the stress applied to the first inorganic insulating layer 11a by the third filled portion 19c disposed in the voids in the first inorganic insulating layer 11a and to reduce occurrence of cracks in the first inorganic insulating layer 11a which are caused by the stress. The void V is desirably set to 0.3 μm or more and 5 μm or less in height of the first inorganic insulating layer 11a in the thickness direction thereof in the cross section, and 0.3 μm or more and 5 μm or less in width of the first inorganic insulating layer 11a in the planar direction thereof in the cross section.

As described above, the voids V are surrounded with the first inorganic insulating particles 13a and the second inorganic insulating particles 13b in a cross section cut along the thickness direction; however, in a three-dimensional shape, a part of the voids extends along the orthogonal direction (Y direction) with respect to the cross section, and another part of the voids extends along the thickness direction (Z direction) of the first inorganic insulating layer 11a so that the voids are connected to the openings O formed on one main surface of the first inorganic insulating layer 11a, which is in contact with the first resin layer 10a, and form open voids. Therefore, a part of the first resin layer 10a fills the voids V through the openings O. The opening O is desirably set to 1 μm or more and 20 μm or less in width along the planar direction.

Meanwhile, a part of the first resin layer 10a fills the voids V through the openings O; however, instead of the first resin layer 10a, a part of the third resin layer 10c may fill the openings, or a part of both the first resin layer 10a and the third resin layer 10c may fill the openings. In the latter case, the first resin layer 10a preferably fills more of the openings O than the third resin layer 10c.

In addition, the third filled portion 19c does not need to fully fill the voids V, and a part of the first resin layer may be disposed in the voids V.

In the embodiment, 20% by volume or more and 40% by volume or less of the first inorganic insulating particles 13a are included in the first inorganic insulating layer 11a, and, for example, 60% by volume or more and 80% by volume or less of the second inorganic insulating particles 13b are included in the first inorganic insulating layers 11a. The reason why the upper limit value of the first inorganic insulating particles 13a and the lower limit value of the second inorganic insulating particles 13b differ from those in the first embodiment is that the voids V can be easily formed in regions among a plurality of the second inorganic insulating particles 13b as the second inorganic insulating particles 13b are increased to a certain extent.

The first inorganic insulating layer 11a desirably has a three-dimensional net-shaped structure by mutually connecting the first inorganic insulating particles 13a and the second inorganic insulating particles 13b. As a result, it is possible to enhance the effect of the inorganic insulating layer 11 for reducing cracks by the third filled portion 19c.

In addition, the first inorganic insulating layer 11a desirably has the first inorganic insulating particles 13a interposed between the second inorganic insulating particles 13b and the third filler portion 19c. As a result, it is possible to enhance the wetting properties of the surface of the first inorganic insulating layer 11a with respect to the third filled portion 19c by the first inorganic insulating particles 13a compared to a case in which the surface of the second inorganic insulating particles 13b are in direct contact with the third filled portion 19c, and to efficiently fill the third filled portion 19c in the void V.

In addition, like the embodiment, the first inorganic insulating layer 11a desirably has second protruding portions 18b that protrude toward the third filled portion 19c from the inner wall of the void V and have at least a part of second inorganic insulating particles 13b. In this case, since large protrusions and recesses are formed on the surface of the inner wall of the void V, the adhesion strength between the first inorganic insulating layer 11a and the third filled portion 19c is increased by the anchor effect, and separation between the first inorganic insulating layer 11a and the third filled portion 19c can be reduced. The second protruding portion 18b is set to, for example, 0.1 μm or more and 2 μm or less in length in the protrusion direction, and, for example, 0.1 μm or more and 2 μm or less in width. Meanwhile, the second protruding portion 18b may have a plurality of the second inorganic insulating particles 13b.

In addition, like the embodiment, it is desirable that the second protruding portion 18b has a pair of wide width portions 20a and a narrow width portion 20b disposed therebetween, and the narrow width portions 20b and the side surfaces of the wide width portions 20a compose depressed portions D. In this case, it is possible to increase the adhesion strength between the first inorganic insulating layer 11a and the third filled portion 19c by the anchor effect of the depressed portions D. The depressed portion D is formed by, for example, connecting the first inorganic insulating particles 11b and the second inorganic insulating particles so as to include the first inorganic insulating particle 13a having a small particle diameter interposed between a pair of the second inorganic insulating particles 13b having a large particle diameter as shown in FIG. 12B.

In addition, the first inorganic insulating layer 11a desirably has third protruding portions 18c that protrude toward the first resin layer 10a and have at least a part of second inorganic insulating particles 13b. As a result, the adhesion strength between the first resin layer 10a and the first inorganic insulating layer 11a is increased by the anchor effect of the third protruding portions 18c, and separation between the first resin layer 10a and the first inorganic insulating layer 11a can be reduced.

In addition, as shown in FIG. 13A, it is desirable that the void V has a long and thin shape in a cross section cut along the planar direction, and the third filled portion 19c also has a long and thin shape. In this case, even when heat is applied to the circuit board 3 so as to cause warpage, the third filled portions 19c are deformed so as to extend along the planar direction, whereby a tensile stress applied to the first inorganic insulating layer 11a can be reduced, and, furthermore, cracks in the first inorganic insulating layer 11a can be reduced.

As shown in FIG. 13B, the void V desirably has a curved portion V1 in the cross-sectional view in the planar direction. As a result, in a case in which heat is applied to the circuit board 3 so as to cause warpage, the third filled portion 19c becomes liable to deform so as to extend along the planar direction due to the spring effect of the curved portion V1, and it is possible to more effectively reduce a tensile stress applied to the first inorganic insulating layer 11a.

In addition, it is desirable that the third filled portion 19c has a third filler composed of third filler particles that are formed of an inorganic insulating material, and the content of the third filler is smaller than that of the first filler 12 included in the first resin layer 10a. As a result, the content of the resin material in the third filled portion 19c is increased, and it is possible to enhance the effect of the first inorganic insulating layer 11a for reducing cracks by the third filled portion 19c. The content of the third filler 12 in the third filled portion 19c is set to, for example, 0% by volume or more and 10% by volume or less, and is set to, for example, 0% or more and 30% or less of the content of the first filler 12 in the first resin layer 10A.

Meanwhile, as shown in FIG. 13B, the second inorganic insulating layer 11b disposed on the second resin layer 10b also has the same structure as for the first inorganic insulating layer 11a. In addition, in the second inorganic insulating layer 11b, the void V is filled with a part of the second resin layer 10b (fourth filled portion 19d).

The first and second inorganic insulating layers 11a and 11b of the embodiment as described above can be formed in the following manner.

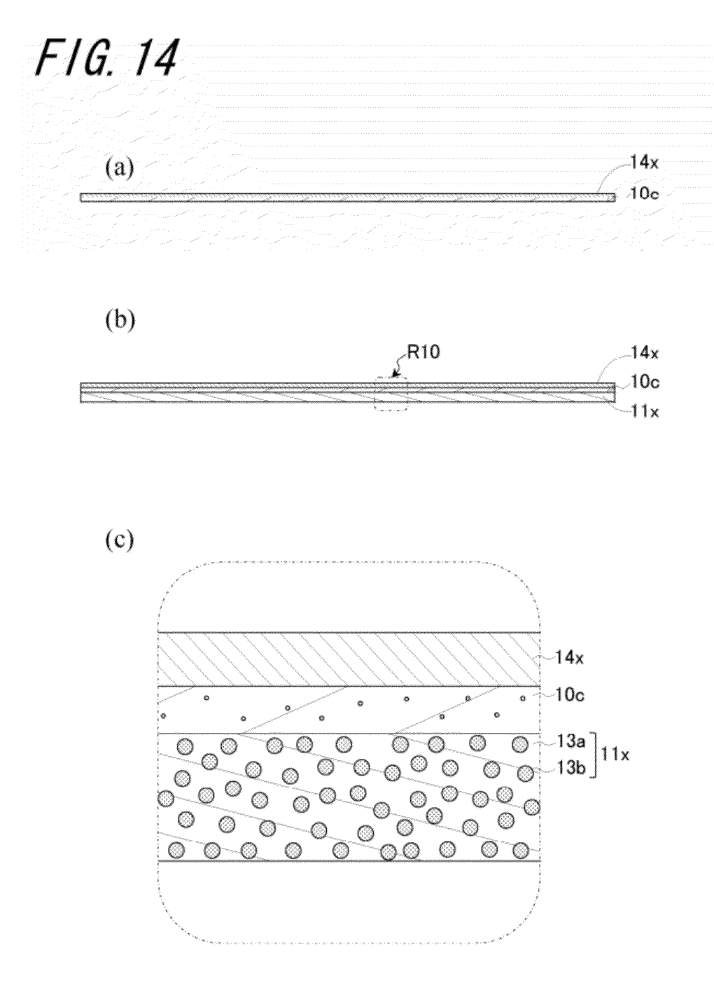

(1B) As shown in FIG. 14A, in the step (2) in the first embodiment, a resin-attached metal foil having the third resin layer 10c and the metal foil 14x is prepared, and, as shown in FIGS. 14B and 14C, the inorganic insulating sol 11x is applied to one main surface of the third resin layer 10c.

Here, the inorganic insulating sol 11x that is used includes 20% by volume or more and 40% by volume or less of the first inorganic insulating particles 13a as the solid content, and 60% by volume or more and 80% by volume or less of the second inorganic insulating particles 13b.

The resin-attached metal foil can be formed by applying a resin varnish to the metal foil 14x using a bar coater, a die coater, a curtain coater, or the like, and drying the resin varnish. The third resin layer 10c formed in the present step is, for example, B-stage or C-stage.

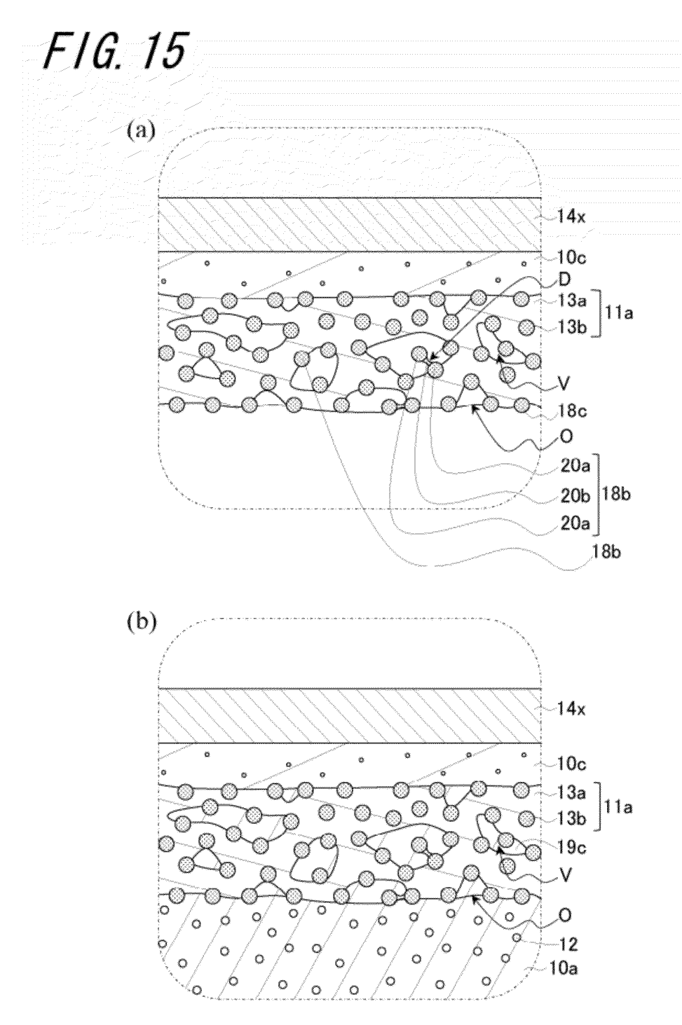

(2B) As shown in FIG. 15A, the solvent of the inorganic insulating sol 11x is evaporated in the step (3) in the first embodiment.

Here, when the inorganic insulating sol 11x includes 60% by volume or more of the second inorganic insulating particles 13b having a particle diameter of 0.5 μm or more, the second inorganic insulating particles 13b come close to each other, and a number of regions surrounded with the second inorganic insulating particles 13b are formed. When the solvent filled in the gaps among the second inorganic insulating particles 13b is evaporated in the above state, shrinkage of the first inorganic insulating particles 13a occurs in the gaps, and voids V are formed. As a result, it is possible to form voids V surrounded with the first inorganic insulating particles 13a and the second inorganic insulating particles 13b.

In addition, when 60% by volume or more of the second inorganic insulating particles 13b having a particle diameter of 0.5 μm or more are included, the second inorganic insulating particles 13b easily come close to each other. Meanwhile, the solvent is liable to remain in facing regions of the second inorganic insulating particles 13b, and a number of the first inorganic insulating particles 13a are included in the remaining solvent. In addition, when the remaining solvent is evaporated, the first inorganic insulating particles 13a that are included in the solvent aggregate in the facing regions of the second inorganic insulating particles in accordance with the evaporation of the solvent. As a result, it is possible to interpose the first inorganic insulating particles 13a between the second inorganic insulating particles 13b. In order to interpose the first inorganic insulating particles 13a between the second inorganic insulating particles 13b, the solid content of the inorganic insulating sol 11x desirably includes 20% by volume or more of the first inorganic insulating particles 13a.

In addition, since the solvent is evaporated in regions including the first inorganic insulating particles 13a more than regions including the second inorganic insulating particles 13b, and the first inorganic insulating particles are shrunk, the third protruding portions 18c are formed.

Meanwhile, the voids V can be formed into a desired shape by appropriately adjusting the particle diameter or content of the first inorganic insulating particles 13a or the second inorganic insulating particles 13b, the kind or amount of the solvent in the inorganic insulating sol 11x, the drying time, the drying temperature, the air volume or wind speed during drying, or the heating temperature or the heating time after drying.

(3B) In the step (4) in the first embodiment, the heating temperature of the inorganic insulating sol 11x is set to the boiling point of the solvent to a temperature lower than the thermal decomposition onset temperature of the third resin layer 10c.

As a result, it is possible to suppress degradation of the characteristics of the third resin layer 10c. Meanwhile, in a case in which the third resin layer 10c is composed of an epoxy resin, the thermal decomposition onset temperature is approximately 280° C. In addition, the thermal decomposition onset temperature is a temperature at which the mass of the resin is decreased by 5% in a thermogravimetric measurement according to ISO 11358:1997.

(4B) As shown in FIG. 15B, in the step (6) in the first embodiment, a part of the first resin layer 10a fills the voids V during heating and pressurization. In addition, similarly, in the step (10) in the first embodiment, a part of the second resin layer 10b fills the voids V during heating and pressurization.

The first and second inorganic insulating layers 11a and 11b of the embodiment can be formed in the above manner.

The invention is not limited to the above embodiments, and a variety of alterations, improvements, combinations, and the like are permitted within the scope of the purport of the invention.

In the above embodiments, examples in which the invention is applied to the circuit board have been described, but the invention can be applied not only to the circuit board but also to all structures having inorganic insulating layers that include the first inorganic insulating particles and the second inorganic insulating particles as described above. For example, the invention can also be applied to chassis of electronic devices, such as mobile phones. In this case, the inorganic insulating layer is used as an abrasion-resistant protective film that protects the chassis. In addition, the invention can also be used for windows used in automobiles or houses. In this case, the inorganic insulating layer can be used as a transparent and abrasion-resistant membrane that coats the window surfaces, and, consequently, it is possible to suppress reduction of the transparency which is caused by damage on the surfaces of window materials. In addition, the invention can also be used for metal molds that are used for die casting. In this case, the inorganic insulating layer can be used as an abrasion-resistant membrane or an insulating film that coats the surfaces of metal molds. In addition, particularly, the inorganic insulating layer in the third embodiment can be used as porous bodies for filters which coat the surfaces of filters formed of a resin fiber or the like. In this case, the inorganic insulating layer in the third embodiment can be used for catalyst carriers of gasoline engines or dust removal filters for diesel engines.

In addition, in the embodiments of the invention as described above, the build-up multilayer substrate composed of a core substrate and circuit layers has been described as an example of the circuit board according to the invention, but examples of the circuit board of the invention include not only the build-up multilayer substrate but also an interposer substrate, a single layer substrate composed of only a coreless substrate or a core substrate, a ceramic substrate, a metal substrate, and a core substrate including a metal plate.

In addition, in the embodiments of the invention as described above, the inorganic insulating layer includes the first inorganic insulating particles and the second inorganic insulating particles, but the inorganic insulating layer may include inorganic insulating particles having a different particle diameter from the first inorganic insulating particles and the second inorganic insulating particles as long as the inorganic insulating layer includes the first inorganic insulating particles and the second inorganic insulating particles.

In addition, in the embodiments of the invention as described above, the first inorganic insulating particles include the third inorganic insulating particles and the fourth inorganic insulating particles, but the first inorganic insulating particles may only include any one of the third inorganic insulating particles and the fourth inorganic insulating particles. In this case, the first inorganic insulating particles desirably include the third inorganic insulating particles only in view of a connecting strength.

In addition, in the embodiments of the invention as described above, the first resin layer and the second resin layer are formed of a thermosetting resin, but at least one or both of the first resin layer and the second resin layer may also be formed of a thermosetting resin. Examples of the thermosetting resin that can be used include a fluororesin, an aromatic liquid crystal polyester resin, a polyether ketone resin, a polyphenylene ether resin, and a polyimide resin.

In addition, in the embodiments of the invention as described above, both the core substrate and the circuit layer have the inorganic insulating layers, but the circuit board may have at least any one of the core substrate and the circuit layer include the inorganic insulating layers.

In addition, in the embodiments of the invention as described above, the evaporation of the solvent in the step (3) and the heating of the solvent in the step (4) are carried out separately, but the steps (3) and (4) may be carried out at the same time.

In addition, in the embodiments of the invention as described above, the uncured second resin precursor sheet is placed on the second inorganic insulating layer in the step (6), but the uncured liquid-phase second resin layer precursor may be applied to the second inorganic insulating layer.

In addition, the core substrate and the circuit layers may be combined in any manner in the first to third embodiments as described above.

Furthermore, the third resin layer in the third embodiment as described above may be added to the circuit board according to the first and second embodiments.

### Examples

Hereinafter, the invention will be described in detail using examples, but the invention is not limited to the following examples, and any alteration and embodiments within the scope of the purport of the invention are included in the scope of the invention.

(Evaluation Method)

A laminated plate having the metal foil, the first inorganic insulating layer composed of inorganic insulating particles, and the first resin layer was produced, a polished cross section of the laminated plate which was cut in the thickness direction thereof was photographed using a field emission scanning electron microscope (manufactured by JEOL Ltd., JSM-7000F), and the presence and absence of cracks were observed in the inorganic insulating layer.

(Conditions for Producing Laminated Plate)

Firstly, a second inorganic insulating sol including a first inorganic insulating sol that included the first inorganic insulating particles and the second inorganic insulating particles was prepared.

As the first inorganic insulating sol, any of “PGM-ST,” “IPA-ST-ZL,” and “IPA-ST-L,” manufactured by Nissan Chemical Industries, Ltd., was used.

In addition, as the second inorganic insulating sol, any of “QUARTRON SP-1B,” manufactured by Fuso Chemical Co., Ltd., and “HIPRESICA FQ N2N,” manufactured by UBE NITTO KASEI CO., LTD., was used.

Next, the first inorganic insulating sol and the second inorganic insulating sol were combined into a predetermined amount, fed into a plastic container, stirred using plastic balls, and uniformly mixed.

Inorganic insulating sols of Samples 1 to 22 were prepared by the above method. The inorganic insulating sols of Samples 1 to 22 include the first inorganic insulating particles and the second inorganic insulating particles having the particle diameters and solid content ratios (% by volume in the solid content) as shown in Table 1, and 45% by weight to 71% by weight of the solvent.

Next, the inorganic insulating sols of Samples 1 to 22 were applied onto the metal foil or onto the third resin layer of the resin-attached metal foil. The third resin layer was formed of an epoxy resin.

Next, the surface of the inorganic insulating sol of Sample 16 was covered with a lid, and placed to stand idle for 20 minutes, whereby the second inorganic insulating particles settle.

Next, the inorganic insulating sols were heated under conditions of temperature: 150° C., time: 2 hours, and atmosphere: the atmosphere, and the solvent was evaporated, thereby producing laminate sheets.

Next, the laminate sheets were laminated on the top and bottom surfaces of the first resin precursor sheet including the uncured thermosetting resin, and the laminate was heated and pressed under conditions of time: 1 hour, pressure: 3 MPa, and temperature: 180° C., thereby making the first resin precursor sheet into a first resin layer so as to produce a laminated plate.

TABLE 1

| | First inorganic insulating particles | | | | | | Second inorganic insulating particles | | |
|---|---|---|---|---|---|---|---|---|---|
| | | Average | Solid | | Average | Solid | | Average | Solid |
| | Product | particle | content | Product | particle | content | Product | particle | content |
| Sample | name | diameter | proportion | name | diameter | proportion | name | diameter | proportion |
| 1 | PGM-ST | 10-15 nm | 100 | | | | | | |
| 2 | PGM-ST | 10-15 nm | 90 | | | | QUARTRON | 1 μm | 10 |
| | | | | | | | SP-1B | | |
| 3 | PGM-ST | 10-15 nm | 80 | | | | QUARTRON | 1 μm | 20 |
| | | | | | | | SP-1B | | |
| 4 | PGM-ST | 10-15 nm | 60 | | | | QUARTRON | 1 μm | 40 |
| | | | | | | | SP-1B | | |
| 5 | PGM-ST | 10-15 nm | 50 | | | | QUARTRON | 1 μm | 50 |
| | | | | | | | SP-1B | | |
| 6 | PGM-ST | 10-15 nm | 50 | | | | HIPRESICA | 2 μm | 50 |
| | | | | | | | FQ N2N | | |
| 7 | PGM-ST | 10-15 nm | 40 | | | | QUARTRON | 1 μm | 60 |
| | | | | | | | SP-1B | | |
| 8 | PGM-ST | 10-15 nm | 30 | | | | QUARTRON | 1 μm | 70 |
| | | | | | | | SP-1B | | |
| 9 | | | | IPA-ST-L | 40-50 nm | 50 | QUARTRON | 1 μm | 50 |
| | | | | | | | SP-1B | | |
| 10 | | | | IPA-ST-ZL | 70-100 nm | 50 | QUARTRON | 1 μm | 50 |
| | | | | | | | SP-1B | | |
| 11 | PGM-ST | 10-15 nm | 20 | IPA-ST-L | 40-50 nm | 20 | QUARTRON | 1 μm | 60 |
| | | | | | | | SP-1B | | |
| 12 | PGM-ST | 10-15 nm | 25 | IPA-ST-ZL | 70-100 nm | 25 | QUARTRON | 1 μm | 50 |
| | | | | | | | SP-1B | | |
| 13 | PGM-ST | 10-15 nm | 22.5 | IPA-ST-ZL | 70-100 nm | 22.5 | QUARTRON | 1 μm | 55 |
| | | | | | | | SP-1B | | |
| 14 | PGM-ST | 10-15 nm | 15 | IPA-ST-ZL | 70-100 nm | 30 | QUARTRON | 1 μm | 55 |
| | | | | | | | SP-1B | | |
| 15 | PGM-ST | 10-15 nm | 30 | IPA-ST-ZL | 70-100 nm | 15 | QUARTRON | 1 μm | 55 |
| | | | | | | | SP-1B | | |
| 16 | PGM-ST | 10-15 nm | 50 | | | | HIPRESICA | 2 μm | 50 |
| | | | | | | | FQ N2N | | |
| 17 | PGM-ST | 10-15 nm | 25 | IPA-ST-ZL | 70-100 nm | 25 | QUARTRON | 1 μm | 50 |
| | | | | | | | SP-1B | | |
| 18 | PGM-ST | 10-15 nm | 20 | IPA-ST-ZL | 70-100 nm | 20 | QUARTRON | 1 μm | 60 |
| | | | | | | | SP-1B | | |
| 19 | PGM-ST | 10-15 nm | 17.5 | IPA-ST-ZL | 70-100 nm | 17.5 | QUARTRON | 1 μm | 65 |
| | | | | | | | SP-1B | | |
| 20 | PGM-ST | 10-15 nm | 15 | IPA-ST-ZL | 70-100 nm | 15 | QUARTRON | 1 μm | 70 |
| | | | | | | | SP-1B | | |
| 21 | PGM-ST | 10-15 nm | 12.5 | IPA-ST-ZL | 70-100 nm | 12.5 | QUARTRON | 1 μm | 75 |
| | | | | | | | SP-1B | | |
| 22 | PGM-ST | 10-15 nm | 10 | IPA-ST-ZL | 70-100 nm | 10 | QUARTRON | 1 μm | 80 |
| | | | | | | | SP-1B | | |

### Examples

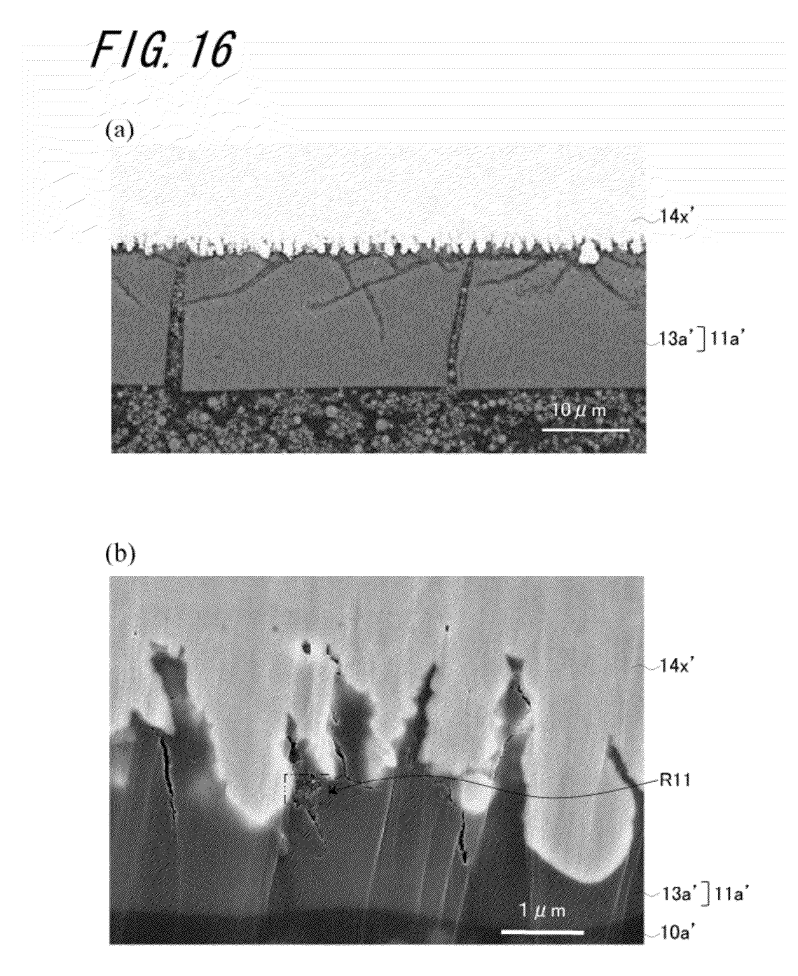

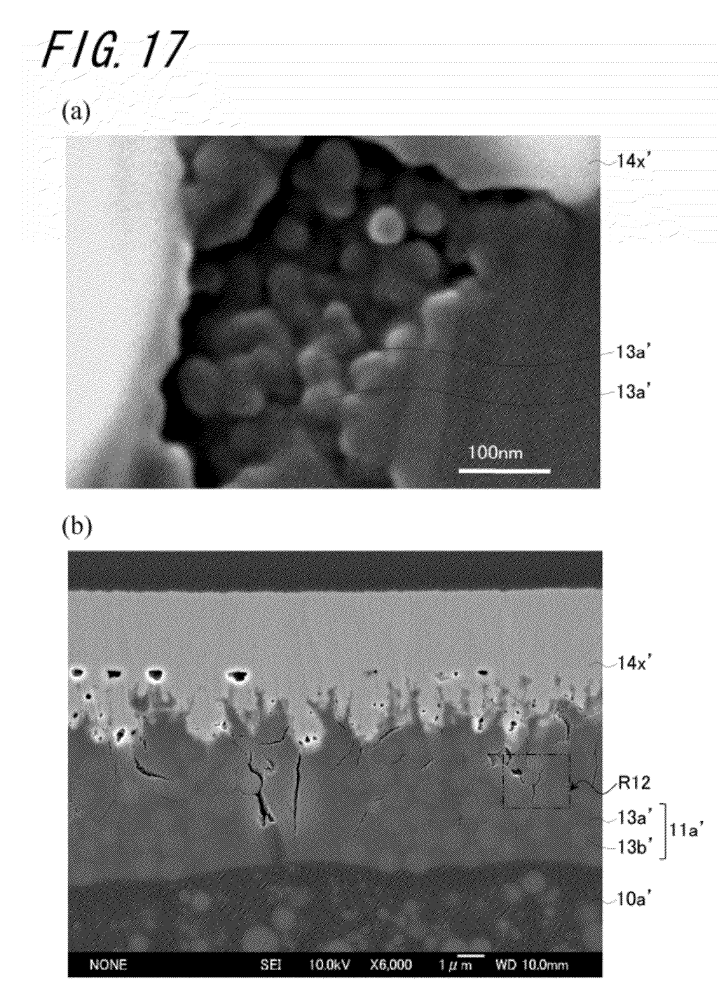

In Sample 1, it was observed that a first inorganic insulating layer 11a′ was formed as shown in FIGS. 16A and 16B, and, first inorganic insulating particles 13a′ were connected to each other as shown in FIGS. 16B and 17A.

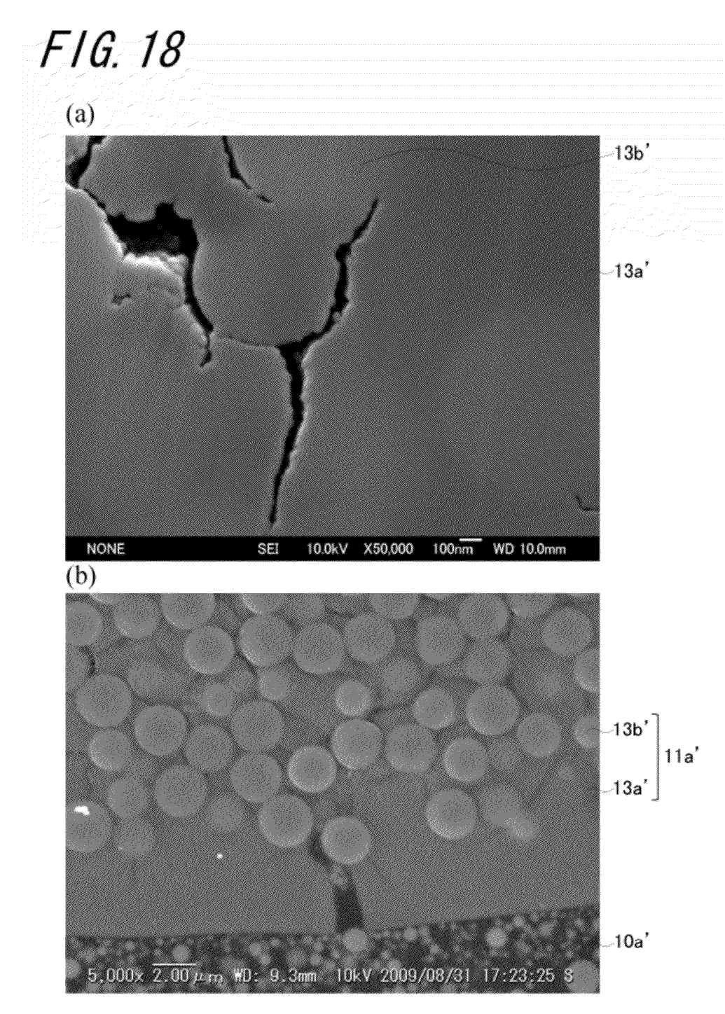

In Samples 5 and 6, as shown in FIGS. 17B to 18B, extension of cracks along the thickness direction in the first inorganic insulating layer 11a′ was reduced compared to in Sample 1. In addition, in Samples 2 to 4 and 7 to 10, similarly to Samples 5 and 6, extension of cracks along the thickness direction in the first inorganic insulating layer 11a′ was reduced compared to in Sample 1.

In addition, in Sample 5, as shown in FIGS. 17B to 18B, extension of cracks between the second inorganic insulating particles 13b′ was reduced compared to in Sample 6.

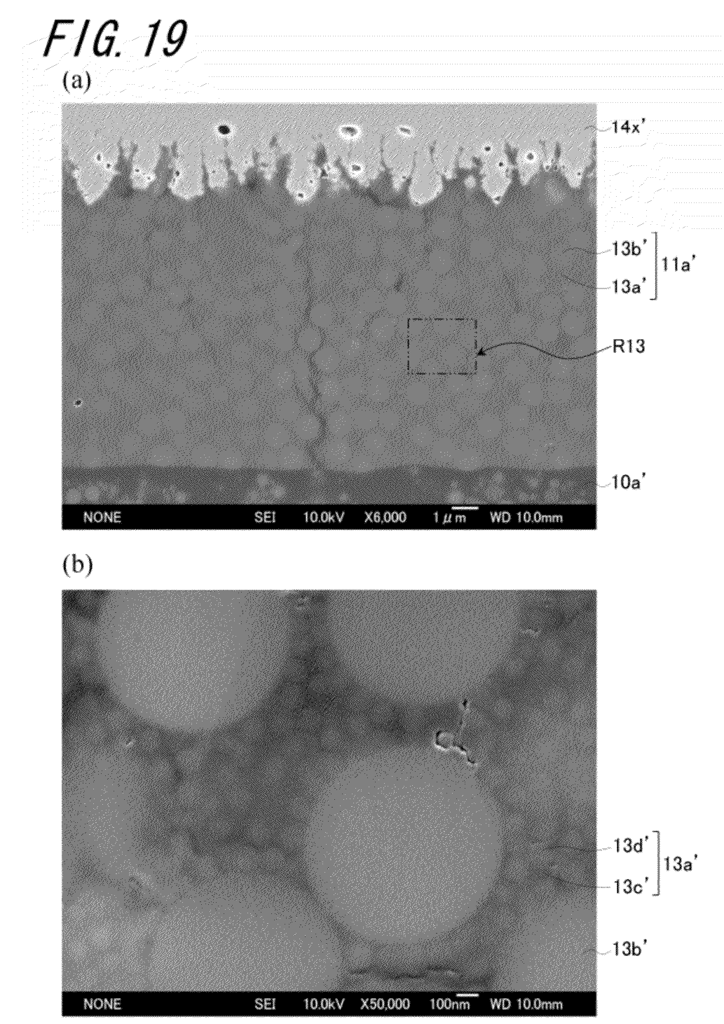

In Sample 12, as shown in FIGS. 19A and 19B, extension of cracks between the second inorganic insulating particles 13b′ was reduced compared to in Samples 5 and 6. In addition, in Samples 11, 13 to 15, similarly to Sample 12, extension of cracks between the second inorganic insulating particles 13b′ was reduced compared to in Samples 5 and 6.

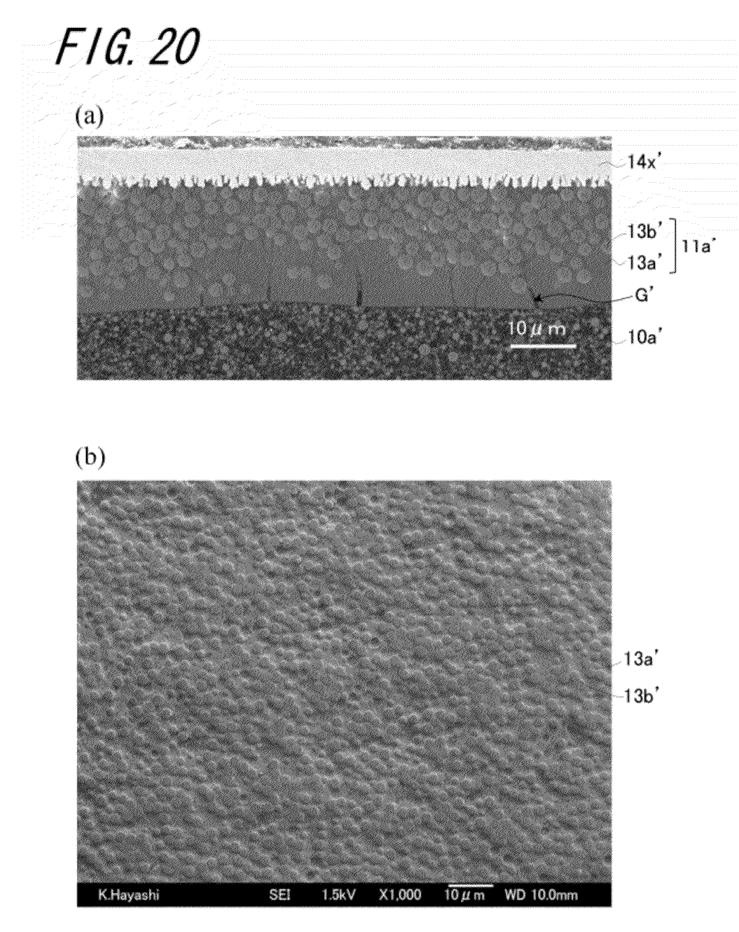

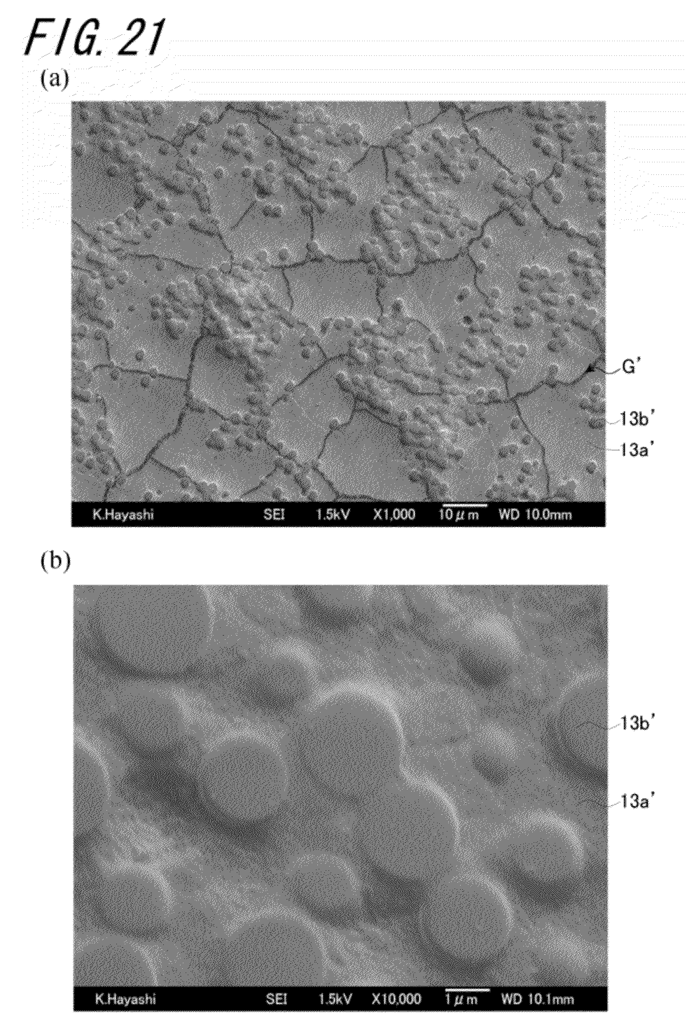

On the other hand, in Sample 16, as shown in FIGS. 20A to 21B, the second inorganic insulating particles 13b′ were included more on the top surface side (the metal foil 14x′ side) than on the bottom surface side (the first resin layer 10a′ side). In addition, in Sample 17, an opening was provided only on the bottom surface side (the first resin layer 10a′ side), and groove portions G′ filled with a part of the first resin layer 10a′ was formed.

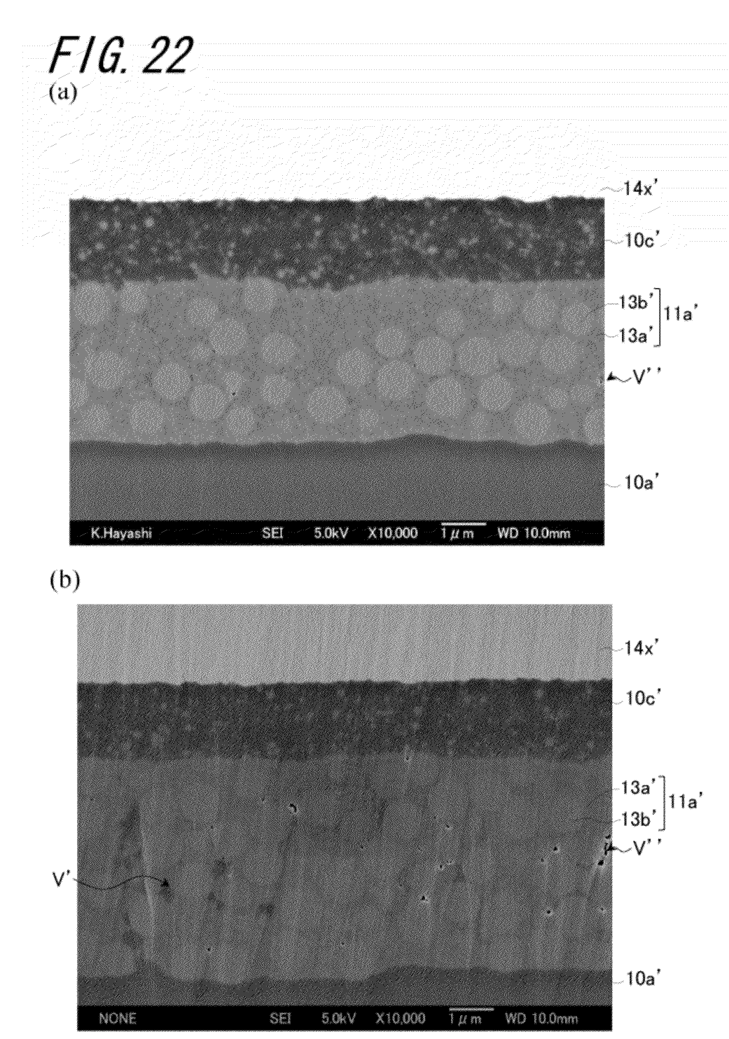

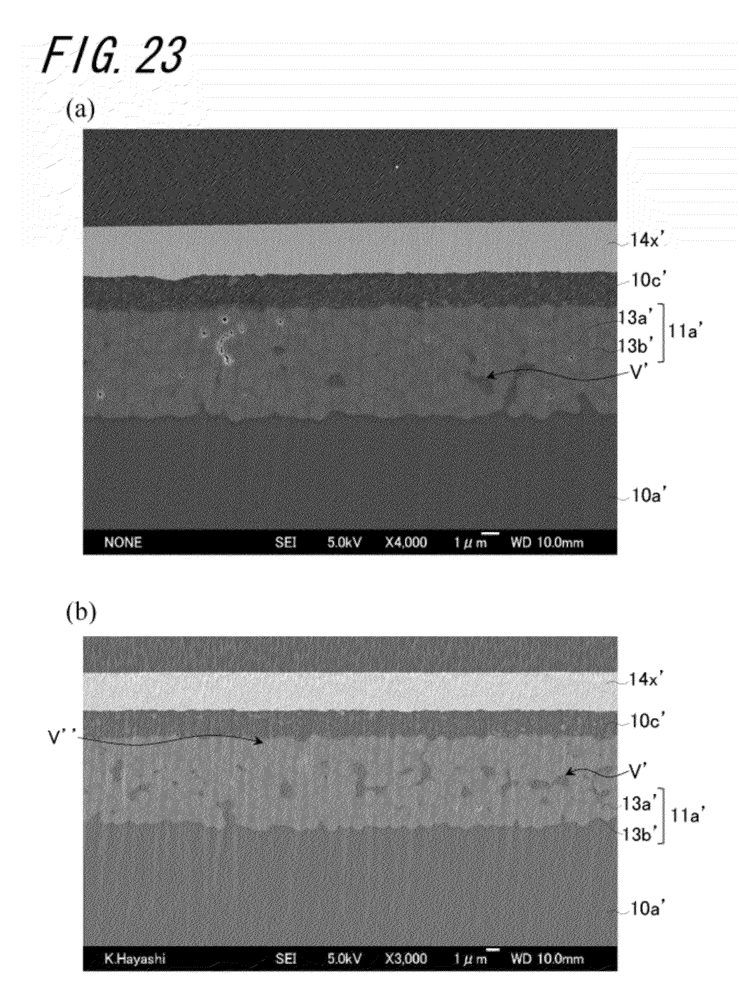

In Sample 17, as shown in FIG. 22A, voids V″ in which a part of the first resin layer 10a′ was not disposed were formed, but voids V′ in which a part of the first resin layer 10a′ was disposed were not formed.

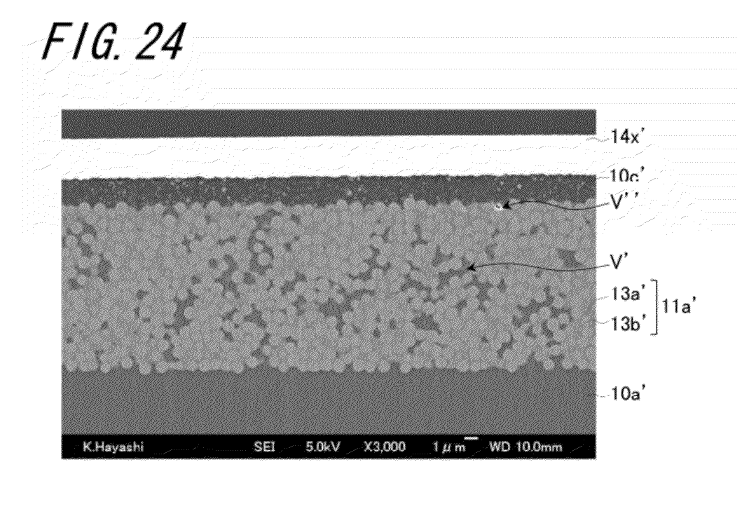

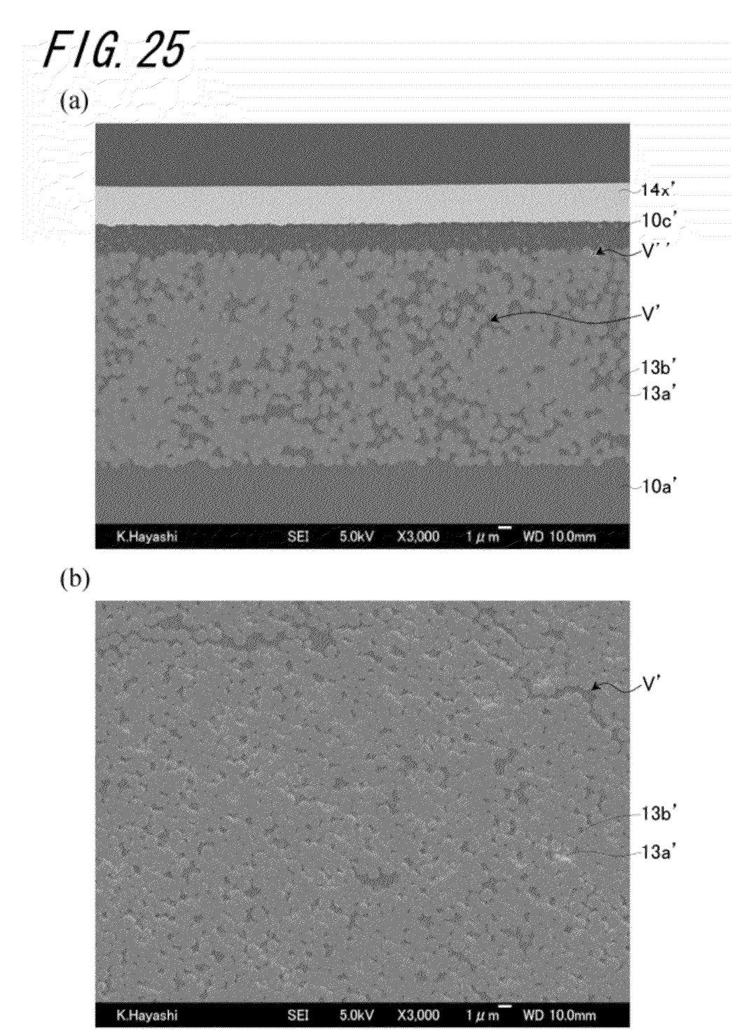

In Samples 18 to 22, as shown in FIGS. 22B to 25B, the second inorganic insulating particles 13b′ were connected to each other via the first inorganic insulating particles 13a′, and voids V′ that were surrounded with the first inorganic insulating particles 13a′ and the second inorganic insulating particles 13b′ in a cross section along the thickness direction, and had a part of the first resin layer 10a′ disposed therein were formed. In addition, as the solid content ratio of the second inorganic insulating particles 13b′ was increased, the voids V′ in which a part of the first resin layer 10a′ was disposed were increased and enlarged so as to form complex shapes.

### REFERENCE SIGNS LIST

1: Mounting structure
2: Electronic component
3: Circuit board
4: Bump
5: Core substrate
6: Circuit layer
7: Base
8: Through hole conductor
9: Insulating body
10a: First resin layer
10ax: First resin precursor sheet
10b: Second resin layer
10bx: Second resin precursor sheet
11a: First inorganic insulating layer
11b: Second inorganic insulating layer
11x: Inorganic insulating sol
12: Filler
13a: First inorganic insulating particle
13b: Second inorganic insulating particle
13c: Third inorganic insulating particle
13d: Fourth inorganic insulating particle
14: Conductive layer
14x: Metal foil
15: Via conductor
16: Laminate sheet
17a: First inorganic insulating portion
17b: Second inorganic insulating portion
18a: First protruding portion
18b: Second protruding portion
18c: Third protruding portion
19a: First filled portion
19b: Second filled portion
19c: Third filled portion
19d: Fourth filled portion
20a: Wide width portion
20b: Narrow width portion
G: Groove portion
O: Opening
V: Void
D: Depressed portion

What is claimed is:

1. A structure, comprising:
an inorganic insulating layer comprising first inorganic insulating particles connected to each other, and second inorganic insulating particles connected to each other via the first inorganic insulating particles and having a larger particle diameter than a particle diameter of the first inorganic insulating particles.

2. The structure according to claim 1,
wherein the particle diameter of the first inorganic insulating particles is within a range of 3 nm or more and 110 nm or less, and
the particle diameter of the second inorganic insulating particles is within a range of 0.5 μm or more and 5 μm or less.

3. The structure according to claim 2,
wherein the first inorganic insulating particles and the second inorganic insulating particles are in an amorphous state.

4. The structure according to claim 2,
wherein the first inorganic insulating particles comprise third inorganic insulating particles whose particle diameter is within a range of 3 nm or more and 15 nm or less, and fourth inorganic insulating particles whose particle diameter is within a range of 35 nm or more and 110 nm or less, and
the third inorganic insulating particles and the fourth inorganic insulating particles are disposed between the second inorganic insulating particles.

5. The structure according to claim 4,
wherein the fourth inorganic insulating particles are connected to each other via the third inorganic insulating particles.

6. The structure according to claim 5,
wherein the second inorganic insulating particles and the fourth inorganic insulating particles are connected to each other via the third inorganic insulating particles.

7. The structure according to claim 1,
further comprising a conductive layer,
wherein the inorganic insulating layer comprises a first inorganic insulating portion, and a second inorganic insulating portion located closer to the conductive layer than the first inorganic insulating portion, and
wherein a content of the second inorganic insulating particles in the second inorganic insulating portion is larger than a content of the second inorganic insulating particles in the first inorganic insulating portion.

8. The structure according to claim 1,
further comprising a conductive layer,
wherein the inorganic insulating layer comprises a first inorganic insulating portion, and a second inorganic insulating portion located closer to the conductive layer than the first inorganic insulating portion, and
wherein the second inorganic insulating portion comprises the second inorganic insulating particles, and the first inorganic insulating portion does not comprise the second inorganic insulating particles.

9. The structure according to claim 8,
wherein the second inorganic insulating portion comprises a first protruding portion that protrudes toward the first inorganic insulating portion and that comprises the second inorganic insulating particles.

10. The structure according to claim 1,
further comprising a resin layer disposed on a main surface of the inorganic insulating layer,
wherein the inorganic insulating layer comprises a groove portion having an opening on the main surface thereof, and a part of the resin layer is disposed in the groove portion.

11. The structure according to claim 1,
further comprising a resin layer disposed on the inorganic insulating layer,
wherein the inorganic insulating layer comprises a void, and a part of the resin layer is disposed in the void.

12. The structure according to claim 11,
wherein the inorganic insulating layer comprises a second protruding portion that protrudes toward the void and that comprises the second inorganic insulating particles.

13. The structure according to claim 1,
further comprising a resin layer disposed on the inorganic insulating layer,
wherein the inorganic insulating layer comprises a third protruding portion that protrudes toward the resin layer and that comprises the second inorganic insulating particles.

14. A method for manufacturing a structure comprising:
applying an inorganic insulating sol comprising first inorganic insulating particles and second inorganic insulating particles having a larger particle diameter than a particle diameter of the first inorganic insulating particles, and
heating the first inorganic insulating particles and the second inorganic insulating particles at a temperature lower than a crystallization onset temperature of the first inorganic insulating particles and lower than a crystallization onset temperature of the second inorganic insulating particles, and connecting the first inorganic insulating particles to each other, and connecting the second inorganic insulating particles to each other via the first inorganic insulating particles.
